(19) United States
(12) Patent Application Publication
(10) Pub. No.: US 2023/0112698 A1
(43) Pub. Date: Apr. 13, 2023

(54) DISPLAY DEVICE

(71) Applicant: Samsung Display Co., LTD., Yongin-si (KR)

(72) Inventors: Sun Hwa LEE, Yongin-si (KR); Bon Yong KOO, Yongin-si (KR); Su Jin LEE, Yongin-si (KR); Jae Yong JANG, Yongin-si (KR)

(73) Assignee: Samsung Display Co., LTD., Yongin-si (KR)

(21) Appl. No.: 17/885,682

(22) Filed: Aug. 11, 2022

(30) Foreign Application Priority Data
Sep. 24, 2021 (KR) 10-2021-0126565

(51) Int. Cl. H01L 33/62

(52) U.S. Cl. CPC H01L 33/62

(57) ABSTRACT

A display device includes a display area and a non-display area; pixels disposed in the display area; a pad area including pads, the pad area being disposed in the non-display area; first power lines electrically connected to the pixels in the display area; first fan-out lines extending in a first direction in the non-display area, the first fan-out lines being electrically connected to the pads; and a first power connection line extending in a second direction intersecting the first direction in the non-display area, the first power connection line electrically connecting the first power lines to the first fan-out lines. A width of a central part of the first power connection line in the first direction is wider than a width of an outer part of the first power connection line in the first direction.

### CROSS-REFERENCE TO RELATED APPLICATION(S

This application claims priority to and benefits of Korean patent application No. 10-2021-0126565 under 35 U.S.C. § 119 filed on Sep. 24, 2021 in the Korean Intellectual Property Office, the entire contents of which are incorporated herein by reference.

### BACKGROUND

### 1. Technical Field

The disclosure generally relates to a display device.

### 2. Description of the Related Art

Recently, as interest in information displays is increased, research and development of display devices have been continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device that minimizes a line heating problem and improves the light emission uniformity of a display panel.

In accordance with an aspect of the disclosure, a display device may include a display area and a non-display area; pixels disposed in the display area; a pad area including pads, the pad area being disposed in the non-display area; first power lines electrically connected to the pixels in the display area; first fan-out lines extending in a first direction in the non-display area, the first fan-out lines being electrically connected to the pads; and a first power connection line extending in a second direction intersecting the first direction in the non-display area, the first power connection line electrically connecting the first power lines to the first fan-out lines, wherein a width of a central part of the first power connection line in the first direction is wider than a width of an outer part of the first power connection line in the first direction.

The central part of the first power connection line may be disposed between the first fan-out lines.

A distance between the central part of the first power connection line and the pad area may be shorter than a distance between the outer part of the first power connection line and the pad area.

A width of the central part of the first power connection line in the second direction may expand in a direction adjacent to the display area from the pad area.

The display device may further include second power lines electrically connected to the pixels in the display area; and second fan-out lines electrically connected to the pads in the non-display area.

The pads may include a first pad electrically connected to the first fan-out lines; and a second pad electrically connected to the second fan-out lines.

The first fan-out lines may be supplied with a first power source from the first pad, and the second fan-out lines may be supplied with a second power source from the second pad. The first power source may be a high-potential driving power source, and the second power source may be a low-potential driving power source.

The display device may further include third fan-out lines disposed in the non-display area. The first fan-out lines may be disposed on the third fan-out lines.

The first power connection line may include slit patterns at least partially overlapping the third fan-out lines in a plan view.

In accordance with an aspect of the disclosure, a display device may include a display area and a non-display area; pixels disposed in the display area; pads disposed in the non-display area; first power lines electrically connected to the pixels in the display area; first fan-out lines extending in a first direction in the non-display area, the first fan-out lines being electrically connected to the pads; a first power connection line extending in a second direction intersecting the first direction in the non-display area, the first power connection line electrically connecting the first power lines to the first fan-out lines; and an extension part extending from at least one of a side of the first fan-out lines and a side of the first power connection line.

The first fan-out lines, the first power connection line, and the extension part may be disposed on a same layer.

The display device may further include a first conductive layer disposed on a substrate; a second conductive layer disposed on the first conductive layer; a third conductive layer disposed on the second conductive layer; and a fourth conductive layer disposed on the third conductive layer. At least one of the third conductive layer and the fourth conductive layer may include the first fan-out lines, the first power connection line, and the extension part.

The fourth conductive layer may be electrically connected to the third conductive layer through a contact hole penetrating a first via layer disposed between the third conductive layer and the fourth conductive layer.

The display device may further include a fifth conductive layer disposed on the fourth conductive layer. The fifth conductive layer may include the first fan-out lines, the first power connection line, and the extension part.

The fifth conductive layer may be electrically connected to the fourth conductive layer through a contact hole penetrating a second via layer disposed between the fourth conductive layer and the fifth conductive layer.

The display device may further include second power lines electrically connected to the pixels in the display area; and second fan-out lines electrically connected to the pads in the non-display area.

The second fan-out lines and the first fan-out lines may be disposed on a same layer.

The display device may further include third fan-out lines disposed in the non-display area. At least one of the first conductive layer and the second conductive layer may include the third fan-out lines.

The display device may further include a lower conductive layer disposed between the substrate and the first conductive layer. The lower conductive layer may include the third fan-out lines.

At least one of the third conductive layer and the fourth conductive layer may include slit patterns at least partially overlapping the second conductive layer in a plan view.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device in accordance with an embodiment.

FIGS. 2 and 3 are schematic diagrams of an equivalent circuit of pixels in accordance with embodiments of the disclosure.

FIG. 4 is a schematic cross-sectional view illustrating a display panel in accordance with an embodiment.

FIG. 5 is a schematic cross-sectional view illustrating a display panel in accordance with an embodiment.

FIG. 6 is an enlarged schematic plan view of area A shown in FIG. 1.

FIGS. 7 to 11 are schematic cross-sectional views illustrating a display panel in accordance with an embodiment.

FIG. 12 is an enlarged schematic plan view of the area A in accordance with an embodiment.

FIG. 13 is a schematic sectional view illustrating a display panel in accordance with an embodiment.

FIGS. 14 to 17 are views illustrating electronic devices in accordance with various embodiments.

### DETAILED DESCRIPTION OF THE EMBODIMENTS

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms. The embodiments are provided by way of example only so that a person of ordinary skill in the art can fully understand the features in the disclosure and the scope thereof. Therefore, the disclosure can also be defined by the scope of the appended claims.

In the drawings, sizes, thicknesses, ratios, and dimensions of the elements may be exaggerated for ease of description and for clarity. Like numbers refer to like elements throughout.

The terminology used herein is for the purpose of describing embodiments only and is not construed as limiting the disclosure.

As used herein, the singular forms are intended to include the plural forms as well, unless the context clearly indicates otherwise.

For example, as used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When described as that any element is “connected”, “coupled” or “accessed” to another element, it should be understood that it is possible that still another element may “connected”, “coupled” or “accessed” between the two elements as well as that the two elements are directly “connected”, “coupled” or “accessed” to each other.

It will be understood that the terms “connected to” or “coupled to” may include a physical or electrical connection or coupling.

The term “on” that is used to designate that an element or layer is on another element or layer includes both a case where an element or layer is located directly on another element or layer, and a case where an element or layer is located on another element or layer via still another element layer. Like reference numerals generally denote like elements throughout the specification.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure.

Hereinafter, embodiments will be described in more detail with reference to the accompanying drawings.

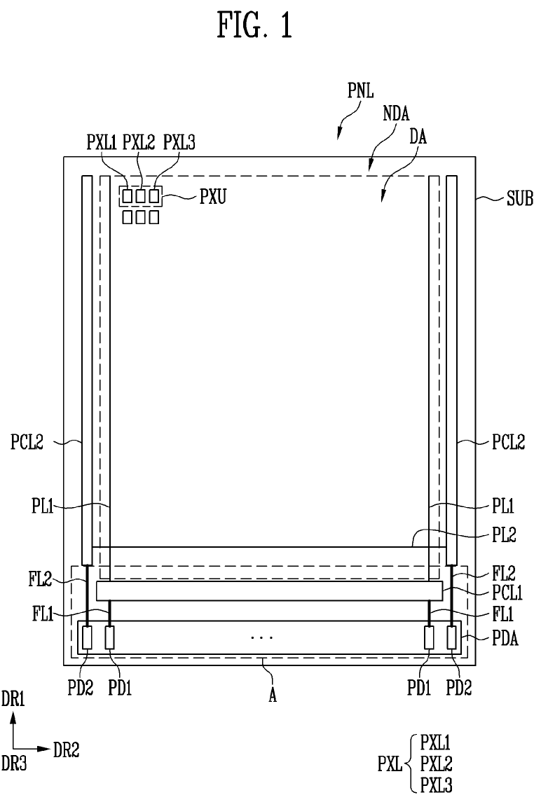

FIG. 1 is a schematic plan view illustrating a display device in accordance with an embodiment.

In FIG. 1, a display device which can use a light emitting element as a light source, for example, a display panel PNL provided in the display device will be illustrated.

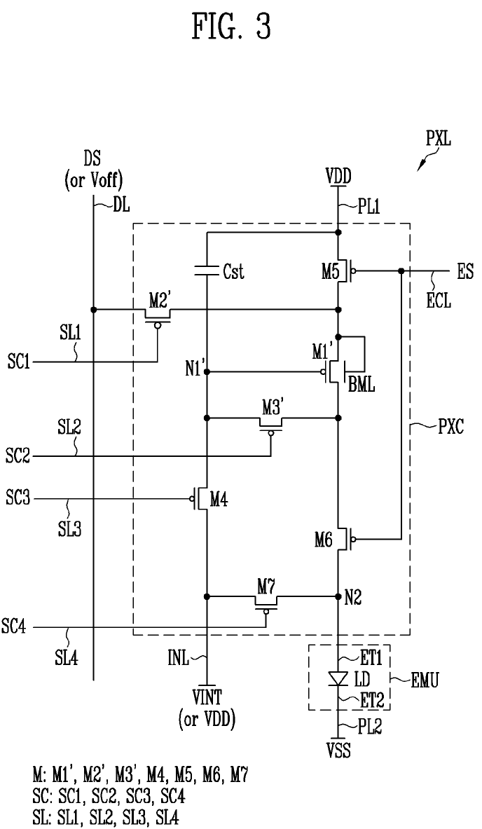

For convenience of description, in FIG. 3, a structure of the display panel PNL will be briefly illustrated based on a display area DA. However, in an embodiment, at least one driving circuit (for example, at least one of a scan driver and a data driver), lines, and/or pads, which are not shown in the drawing, may be further disposed in the display panel PNL.

Referring to FIG. 1, the display panel PNL may include a substrate SUB and a pixel unit PXU disposed on the substrate SUB. The pixel unit PXU may include first pixels PXL1, second pixels PXL2, and/or third pixels PXL3. Hereinafter, in case that at least one pixel among the first pixels PXL1, the second pixels PXL2, and the third pixels PXL3 is arbitrarily designated or in case that two or more kinds of pixels among the first pixels PXL1, the second pixels PXL2, and the third pixels PXL3 are inclusively designated, the corresponding pixel or the corresponding pixels will be referred to as a “pixel PXL” or “pixels PXL.”

The substrate SUB is used to constitute a base member of the display panel PNL, and may be a rigid or flexible substrate or film. In an example, the substrate SUB may be a rigid substrate made of glass or tempered glass, or a flexible substrate (or thin film) made of a plastic or metal material. The material and/or property of the substrate SUB is not particularly limited.

The display panel PNL and the substrate SUB for forming the same may include the display area DA for displaying an image and a non-display area NDA except the display area DA. Pixels PXL may be arranged (or disposed) in the display area DA. Various lines, pads, and/or a built-in circuit, which are connected to the pixels PXL of the display area DA, may be disposed in the non-display area NDA. The pixels PXL may be regularly arranged in the display area DA according to a stripe structure, a PENTILE™ structure, or the like within the spirit and the scope of the disclosure. However, the arrangement structure of the pixels PXL is not necessarily limited thereto, and the pixels PXL may be arranged in the display area DA by using various structures and/or methods.

In an embodiment, two or more kinds of pixels PXL emit lights of different colors. In an example, first pixels PXL1 emitting light of a first color, second pixels PXL2 emitting light of a second color, and third pixels PXL3 emitting light of a third color may be arranged in the display area DA. At least one first pixel PXL1, a least one second pixel PXL2, and at least one third pixel PXL3, which are disposed adjacent to each other, may constitute one pixel unit PXU that emits lights of various colors. For example, each of the first to third pixels PXL1, PXL2, and PXL3 may be a sub-pixel emitting light of a color. In an embodiment, the first pixel PXL1 may be a red pixel emitting light of red, the second pixel PXL2 may be a green pixel emitting light of green, and the third pixel PXL3 may be a blue pixel emitting light of blue. However, the disclosure is not necessarily limited thereto.

In an embodiment, the first pixel PXL1, the second pixel PXL2, and the third pixel PXL3 respectively have light emitting elements emitting light of a same color, and may include color conversion layers and/or color filters of different colors, which are disposed on the respective light emitting elements, to respectively emit lights of the first color, the second color, and the third color. In an embodiment, the first pixel PXL1, the second pixel PXL2, and the third pixel PXL3 respectively have, as light sources, a light emitting element of the first color, a light emitting element of the second color, and a light emitting element of the third color, to respectively emit lights of the first color, the second color, and the third color. However, the color, kind, and/or number of pixels PXL constituting each pixel unit PXU are not particularly limited. In an example, the color of light emitted by each pixel PXL may be variously changed.

The pixel PXL may include at least one light source driven by a control signal (for example, a scan signal and a data signal) and/or a power source (for example, a first power source and a second power source). In an embodiment, the light source may include a subminiature pillar-shaped light emitting element LD having a size small to a degree of nanometer scale to micrometer scale. However, the disclosure is not necessarily limited thereto. Various types of light emitting elements LD may be used as the light source of the pixel PXL.

A power line PL1 and PL2 for supplying a driving voltage to the pixels PXL may be disposed in the display area DA. The power line PL1 and PL2 may include first and second power lines PL1 and PL2.

The first power line PL1 may extend in a first direction DR1, and the second power line PL2 may extend in a second direction DR2 intersecting the first direction DR1. The first power lines PL1 may be arranged to be spaced apart from each other at a specific or given distance along the second direction DR2, and the second power lines PL2 may be arranged to be spaced apart from each other at a specific or given distance along the first direction DR1.

The first power line PL1 may be electrically connected to the pixels PXL in the display area DA. In an example, the first power line PL1 may extend in the first direction DR1, and be commonly connected to pixels PXL sequentially arranged along the second direction DR2. Similarly, the second power line PL2 may extend in the second direction DR2, and be commonly connected to pixels PXL sequentially arranged along the first direction DR1.

The first power line PL1 may be electrically connected to a first power connection line PCL1 which will be described later, to be electrically connected to a first pad PD1 of a pad area PDA through the first power connection line PCL1. In case that the display panel PNL is driven, a voltage of the first power source (for example, a high-potential driving power source) may be supplied to the first pad PD1.

The second power line PL2 may be electrically connected to a second power connection line PCL2 which will be described later, to be electrically connected to a second pad PD2 of the pad area PDA through the second power connection line PCL2. In case that the display panel PNL is driven, a voltage of the second power source (for example, a low-potential driving power source) may be supplied to the second pad PD2.

In an embodiment, each pixel PXL may be an active pixel. However, the kind, structure, and/or driving method of pixels PXL which can be applied to the display device are not particularly limited. For example, each pixel PXL may be a pixel of a passive or active light emitting display device using various structures and/or driving methods.

The non-display area NDA may be area in which lines, a pad, and/or a built-in circuit, which are electrically connected to the pixels PXL, are provided to drive the pixels PXL. In an example, the pad area PDA including fan-out lines FL1 and FL2, power connection lines PCL1 and PCL2, and/or pads PD1 and PD2 may be provided in the non-display area NDA.

The non-display area NDA may be provided at at least one side or a side of the display area DA. The non-display area NDA may surround the circumference (for example, a periphery or an edge) of the display area DA or may be adjacent to the display area DA.

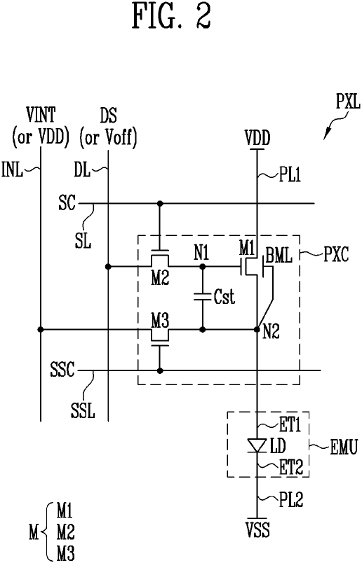

The fan-out lines FL1 and FL2 may be provided in the non-display area NDA, and electrically connect the pads PD1 and PD2 and the pixels PXL to each other. Each of the fan-out lines FL1 and FL2 may extend in the first direction DR1 in the non-display area NDA. In an embodiment, each of the fan-out lines FL1 and FL2 extends in the first direction DR1, and may include a bent part which is bent partially. In an embodiment, the fan-out lines FL1 and FL2 may include a first fan-out line FL1 and a second fan-out line FL2. The first fan-out line FL1 may be electrically connected to the first pad PD1, and be supplied with the first power source (VDD shown in FIG. 2) from the first pad PD1. The second fan-out line FL2 may be electrically connected to the second pad PD2, and be supplied with the second power source (VSS shown in FIG. 2) from the second pad PD2.

The power connection lines PCL1 and PCL2 may be disposed in the non-display area NDA located (or disposed) at at least one side or a side of the display area DA.

The power connection lines PCL1 and PCL2 may function to minimize a voltage drop of the first power source VDD and the second power source VSS. Also, the power connection lines PCL1 and PCL2 may be connected to both end portions of the first and second power lines PL1 and PL2, to supply the voltages of the first and second power sources VDD and VSS to the first and second power lines PL1 and PL2, respectively. Accordingly, a luminance deviation of the pixels PXL due to the voltage drop of the first power source VDD and the second power source VSS can be prevented and reduced.

In an embodiment, the power connection lines PCL1 and PCL2 may include the first power connection line PCL1 and the second power connection line PCL2. The first power connection line PCL1 may electrically connect the first power line PL1 and the first fan-out line FL1. The first power connection line PCL1 may be electrically connected to the first pad PD1 through the first fan-out line FL1. For example, the first power connection line PCL1 may be connected between the first power line PL1 and the first pad PD1, to transfer the voltage of the first power source, which is applied to the first pad PD1 in case that the display panel PNL is driven, to the first power line PL1.

The second power connection line PCL2 may electrically connect the second power line PL2 and the second fan-out line FL2 to each other. The second power connection line PCL2 may be electrically connected to the second pad PD2 through the second fan-out line FL2. For example, the second power connection line PCL2 may be connected between the second power line PL2 and the second pad PD2, to transfer the voltage of the second power source, which is applied to the second pad PD2 in case that the display panel PNL is driven, to the second power line PL2.

In an embodiment, the first power connection line PCL1 may extend in the second direction DR2 in the non-display area NDA. The second power connection line PCL2 may extend in the first direction DR1 in the non-display area NDA. Although a case where the first power connection line PCL1 is disposed at a lower side of the display panel PNL with respect to the display area DA and the second power connection line PCL2 is disposed at each of left and right sides of the display panel PNL with respect to the display area DA is illustrated in the drawing, the disclosure is not necessarily limited thereto. For example, in an embodiment, the first power connection line PCL1 and/or the second power connection line PCL2 may have a closed loop shape surrounding the edge of the display area DA. For example, the first power connection line PCL1 and/or the second power connection line PCL2 may have an opened loop shape in which at least a portion of the first power connection line PCL1 and/or the second power connection line PCL2 is opened. For example, the arrangement of the first power connection line PCL1 and/or the second power connection line PCL2 may be variously changed in an embodiment.

The pads PD1 and PD2 may be disposed in the pad area PDA. The pads PD1 and PD2 may supply (or transfer) power sources and signals, which are used to drive the pixels PXL provided in the display area DA and/or the built-in circuit.

The first pad PD1 may be connected to the first power connection line PCL1 through the first fan-out line FL1, and be electrically connected to the first power line PL1 through the first power connection line PCL1. The second pad PD2 may be connected to the second power connection line PCL2 through the second fan-out line FL2, and be electrically connected to the second power line PL2 through the second power connection line PCL2.

FIGS. 2 and 3 are schematic diagrams of an equivalent circuit of pixels in accordance with embodiments of the disclosure.

In an embodiment, each pixel PXL shown in FIGS. 2 and 3 may be any one of the pixels PXL disposed in the display area DA shown in FIG. 1. For example, each pixel PXL shown in FIGS. 2 and 3 may be any one of the first pixel PXL1, the second pixel PXL2, and the third pixel PXL3. The pixel PXL disposed in the display area DA may have structures substantially identical or similar to one another. The pixels PXL may have various structures in addition to the structures disclosed in the embodiments shown in FIGS. 2 and 3.

Referring to FIGS. 1 and 2, the pixel PXL may be electrically connected to a scan line SL and a data line DL. Also, the pixel PXL may be electrically connected to a first power source VDD (or a first power line PL1) and a second power source VSS (or a second power line PL2). The pixel PXL may be further connected to at least another signal line and/or at least another power line. For example, the pixel PXL may be electrically connected to a control line SSL and an initialization power line INL to which a voltage of an initialization power source VINT is applied.

The pixel PXL may include a light emitting unit EMU for generating light with a luminance corresponding to each data signal DS (or Voff). Also, the pixel PXL may further include a pixel circuit PXC for driving the light emitting unit EMU.

The light emitting unit EMU may include a first electrode ET1, a second electrode ET2, and at least one light emitting elements LD electrically connected between the first and second electrodes ET1 and ET2. The light emitting element LD may be electrically connected to the first power source VDD through the first electrode ET1 and/or the pixel circuit PXC, and be electrically connected to the second power source VSS through the second electrode ET2.

The first power source VDD and the second power source VSS may supply voltages having different potentials. A potential difference between the first power source VDD and the second power source VSS may be higher than or equal to a threshold voltage of the light emitting element LD.

In an embodiment, the light emitting unit EMU may include a single light emitting element LD connected in a forward direction between the pixel circuit PXC and the second power source VSS. In an embodiment, the light emitting unit EMU may include light emitting elements LD connected in the forward direction between the first power source VDD and the second power source VSS. For example, the light emitting unit EMU may include light emitting elements LD connected in parallel, series, or series or parallel between the pixel circuit PXC and the second power source VSS. In an embodiment, each light emitting element LD may be an inorganic light emitting diode manufactured in a small size ranging from nanometer scale to micrometer scale by using a nitride-based semiconductor material, a phosphide-based semiconductor material, or the like, but the disclosure is not necessarily limited thereto. The kind, connection structure, and/or number of light emitting elements LD constituting the light emitting unit EMU may be variously changed in an embodiment.

At least one light emitting element LD connected in the forward direction between the first power source VDD and the second power source VSS may constitute an effective light source of each pixel PXL. In case that a driving current is supplied to each light emitting element LD through the pixel circuit PXC of the corresponding pixel PXL, the light emitting element LD may emit light with a luminance corresponding to the driving current. Accordingly, the pixel PXL may emit light with the luminance corresponding to the driving current.

The pixel circuit PXC may be electrically connected between the first power source VDD and the light emitting unit EMU. Also, the pixel circuit PXC may be electrically connected to the scan line SL and the data line DL, and be supplied with a scan signal SC and a data signal DS respectively from the scan line SL and the data line DL. Also, the pixel circuit PXC may be electrically connected to the control line SSL and the initialization power line INL, and be supplied with a control signal SSC and a voltage of the initialization power source VINT.

The pixel circuit PXC may include at least one transistor M and a capacitor Cst. For example, the pixel circuit PXC may include a first transistor M1, a second transistor M2, a third transistor M3, and the capacitor Cst.

The first transistor M1 may be electrically connected between the first power source VDD and a second node N2. The second node N2 may be a node through which the pixel circuit PXC and the light emitting unit EMU are connected to each other. For example, the second node N2 may be a node through which one electrode (for example, a source electrode) of the first transistor M1 and the first electrode ET1 of the light emitting unit EMU (for example, an anode electrode of the light emitting unit EMU) are connected to each other. A gate electrode of the first transistor M1 may be electrically connected to a first node N1.

The first transistor M1 may be a driving transistor of each pixel PXL. For example, the first transistor M1 may be electrically connected between the first power line PL1 and the first electrode ET1 of each pixel PXL, to control a driving current supplied to the light emitting unit EMU, corresponding to a voltage of the first node N1.

In an embodiment, the first transistor M1 may further include a lower conductive layer BML (also, referred to as a “back gate electrode”). In an embodiment, the lower conductive layer BML may be electrically connected to the one electrode (for example, the source electrode) of the first transistor M1.

In an embodiment in which the first transistor M1 may include the lower conductive layer BML, there may be applied a back-biasing technique (or sync technique) for moving a threshold voltage of the first transistor M1 in a negative direction or positive direction by applying a back-biasing voltage to the lower conductive layer BML of the first transistor M1. In case that the lower conductive layer BML is disposed to overlap a semiconductor pattern constituting a channel of the first transistor M1, the lower conductive layer BML blocks light incident onto the semiconductor pattern, thereby stabilizing operational characteristics of the first transistor M1.

The second transistor M2 may be electrically connected between the data line DL and the first node N1. A gate electrode of the second transistor M2 may be electrically connected to the scan line SL of a corresponding horizontal line. The second transistor M2 may be turned on in case that the scan signal SC having a gate-on voltage (for example, a logic high voltage or a high level voltage) is supplied from the scan line SL, to electrically connect the data line DL and the first node N1 to each other.

The second transistor M2 may be a switching transistor for transferring each data signal DS to the inside of the pixel PXL. For example, for each frame period, a data signal DS of a corresponding frame may be supplied to the data line DL. The data signal DS may be transferred to the first node N1 through the second transistor M2 while the scan signal SC having the gate-on voltage is supplied. For example, for each horizontal period constituting each frame period, the scan signal SC having the gate-on voltage may be simultaneously supplied to pixels PXL of a horizontal line corresponding to the corresponding horizontal period. Accordingly, second transistors M2 provided in the pixels PXL of the corresponding horizontal line are turned on, so that data signals DS respectively supplied to data line DL can be simultaneously supplied to the pixels PXL of the corresponding horizontal line.

A first electrode of the capacitor Cst may be electrically connected to the first node N1. A second electrode of the capacitor Cst may be electrically connected to the second node N2. The capacitor Cst may be a storage capacitor for storing each data signal DS in the pixel PXL. For example, the capacitor Cst may charge a voltage corresponding to the data signal DS supplied to the first node N1 during each frame period.

The third transistor M3 may be electrically connected between the second node N2 and the initialization power line INL. The gate electrode of the third transistor M3 may be electrically connected to the control line SSL of the corresponding horizontal line.

The third transistor M3 may be an initialization transistor for transferring the voltage of the initialization power source VINT to the first electrode ET1 of each pixel PXL during a driving period of the display panel PNL. For example, the third transistor M3 may be turned on by the control signal SSC having the gate-on voltage supplied to a corresponding pixel row. In case that the third transistor M3 is turned on, the voltage of the initialization power source VINT may be transferred to each first electrode ET1 during the driving period of the display panel PNL.

In an embodiment, scan signals SC having the gate-on voltage may be sequentially supplied to scan lines SL of respective pixel rows arranged in the display area DA during the driving period of the display panel PNL. Control signals SSC having the gate-on voltage may be sequentially supplied to control lines SSL of the respective pixel row to be synchronized with the scan signals SC having the gate-on voltage. Accordingly, second and third transistors M2 and M3 of pixels PXL are arranged on a corresponding horizontal line for each horizontal period, so that voltages corresponding to data signals DS supplied to data lines DL (for example, difference voltages between voltages of data signals DS corresponding to the pixels PXL and the voltage of the initialization power source VINT) can be stored in capacitors Cst, respectively.

The third transistor M3 may be turned on by the control signal SSC having the gate-on voltage, which is supplied to a corresponding pixel row during a sensing period for detecting a characteristic of each pixel PXL, etc., within the spirit and the scope of the disclosure. In case that the third transistor M3 is turned on, the second node N2 may be electrically connected to the initialization power line INL. The initialization power line INL may be connected to a sensing circuit during the sensing period. Accordingly, a voltage of the second node N2 may be transferred to the sensing circuit through the initialization power line INL. The voltage of the second node N2, which is transferred to the initialization power line INL may be provided to a driving circuit (for example, a timing controller) via the sensing circuit to be used for compensating form a characteristic deviation of the pixels PXL, and the like within the spirit and the scope of the disclosure.

In an embodiment, the control signals SSC having the gate-on voltage may be sequentially supplied to control lines SSL of the respective pixel rows arranged in the display area DA during the sensing period for detecting characteristics of the pixels PXL, etc., within the spirit and the scope of the disclosure. Accordingly, second nodes N2 of pixels PXL arrange on a corresponding pixel row may be connected to the sensing circuit for each horizontal period. Thus, characteristics of the pixels PXL can be detected through the initialization power line INL during the sensing period.

Although a case where the transistors M included in the pixel circuit PXC are all n-type transistors is illustrated in FIG. 2, the disclosure is not necessarily limited thereto. For example, at least one of the first, second, and third transistors M1, M2, and M3 may be changed to a p-type transistor. The structure and driving method of the pixel circuit PXC and/or the pixel PXL may be variously changed in an embodiment.

The structure and driving method of the pixel circuit PXC and/or the pixel PXL may be variously changed in an embodiment. For example, the pixel circuit PXC may be as shown in an embodiment shown in FIG. 3. In FIG. 3, overlapping descriptions of components similar or identical to those of the embodiment shown in FIG. 2 will be omitted.

Referring to FIGS. 1 to 3, the pixel PXL may be electrically connected to at least one scan line SL (or at least one gate line including the scan line SL) and a data line DL. For example, the pixel PXL may be electrically connected to a first scan line SL1, a second scan line SL2, a third scan line SL3, and a fourth scan line SL4, and the data line DL. Also, the pixel PXL may be connected to a first power source VDD (or a first power line PL1) and a second power source VSS (or a second power line PL2). In an embodiment, the pixel PXL may be further connected to at least another signal line. For example, the pixel PXL may be electrically connected to an emission control line ECL.

In an embodiment, the first scan line SL1, the second scan line SL2, the third scan line SL3, and the fourth scan line SL4 may be supplied with scan signals SC having a gate-on voltage at different times. The first scan line SL1, the second scan line SL2, the third scan line SL3, and the fourth scan line SL4 may be separated from each other.

In an embodiment, at least two scan lines SL among the first scan line SL1, the second scan line SL2, the third scan line SL3, and the fourth scan line SL4 may be supplied with a scan signal SC having the gate-on voltage at the same time, and be integrated as one line or as a line. In an example, the first scan line SL1 and the second scan line SL2 may be supplied with a first scan signal SC1 and a second scan signal SC2, which have the gate-on voltage at the same time. The first scan line SL1 and the second scan line SL2 may be integrated as one scan line SL, and the first scan signal SC1 and the second scan signal SC2 may be substantially the same scan signal SC.

In an embodiment, the first scan line SL1 and the second scan line SL2 may be a scan line(s) SL for transferring the first scan signal SC1 (for example, a current scan signal) having the gate-on voltage to each pixel PXL during a corresponding horizontal period so as to supply data signals DS respectively to pixels PXL of a corresponding horizontal line. The third scan line SL3 may be a scan line SL for transferring a third scan signal SC3 (for example, a previous scan signal) having the gate-on voltage to each pixel PXL prior to the first scan signal SC1 so as to initialize a voltage of each first node N1 before the data signals DS are respectively supplied to the pixels PXL of the corresponding horizontal line. The fourth scan line SL4 may be a scan line SL for transferring a fourth scan signal SC4 having the gate-on voltage to each pixel PXL so as to transfer a voltage of an initialization power source VINT to each second node N2 before or after the data signals DS are respectively supplied to the pixels PXL of the corresponding horizontal line. The fourth scan line SL4 may be integral with at least one of the first scan line SL1, the second scan line SL2, and the third scan line SL3, or be separated from the first scan line SL1, the second scan line SL2, and the third scan line SL3.

In an embodiment, the emission control line ECL may be a control line for transferring an emission control signal ES having the gate-off voltage to each pixel PXL after the scan signals SC are respectively supplied to the first to fourth scan lines SL1, SL2, SL3, and SL4. For example, the emission control signal ES having a gate-off voltage may be supplied to the emission control line ECL while the scan signals SC having the gate-on voltage are supplied to the first to fourth scan lines SL1, SL2, SL3, and SL4. After a voltage corresponding to each data signal DS is charged as scan signals SC having the gate-on voltage are supplied to first to fourth scan lines SL1, SL2, SL3, and SL4 of a corresponding pixel row during each frame period, the emission control signal ES having the gate-off voltage may be supplied to an emission control line ECL of the corresponding pixel row. Accordingly, pixels PXL can emit light with a luminance corresponding to each data signal DS.

A pixel circuit PXC may include transistors M and at least one capacitor Cst. For example, the pixel circuit PXC may include a first transistor M1', a second transistor M2', a third transistor M3', a fourth transistor M4, a fifth transistor M5, a sixth transistor M6, a seventh transistor M7, and the capacitor Cst.

The first transistor M1' may be electrically connected between the first power source VDD and a second node N2. For example, one electrode (for example, a source electrode) of the first transistor M1' may be electrically connected to the first power source VDD via the fifth transistor M5. Another electrode (for example, a drain electrode) of the first transistor M1' may be connected to a first electrode ET1 of a light emitting unit EMU (for example, an anode electrode of the light emitting unit EMU) via the sixth transistor M6. A gate electrode of the first transistor M1' may be electrically connected to a first node N1'. The first transistor M1' may be a driving transistor for controlling a driving current supplied to the light emitting unit EMU, corresponding to a voltage of the first node N1'.

In an embodiment, the first transistor M1' may further include a lower conductive layer BML. In an embodiment, the lower conductive layer BML may be electrically connected to the one electrode (for example, the source electrode) of the first transistor M1'.

The second transistor M2' may be electrically connected between the data line DL and the one electrode (for example, the source electrode) of the first transistor M1'. A gate electrode of the second transistor M2' may be electrically connected to the first scan line SL1 of the corresponding horizontal line. The second transistor M2' may be turned on in case that the first scan signal SC1 having the gate-on voltage from the first scan line SL1, to electrically connect the data line DL to the one electrode of the first transistor M1'. Therefore, in case that the second transistor M2' is turned on, a data signal DS supplied from the data line DL may be transferred to the first transistor M1'.

The third transistor M3' may be connected between the other electrode (for example, the drain electrode) of the first transistor M1' and the first node N1'. A gate electrode of the third transistor M3' may be electrically connected to the second scan line SL2 (or the first scan line SL1) of the corresponding horizontal line. The third transistor M3' may be turned on in case that the second scan signal SC2 (or the first scan signal SC1) having the gate-on voltage from the second scan line SL2 (or the first scan line SL1), to connect the first transistor M1' in a diode form. Therefore, the first transistor M1' may be turned on in a form in which the first transistor M1' is diode-connected during a period in which the second scan signal SC2 (or the first scan signal SC1) having the gate-on voltage is supplied. Accordingly, the data signal DS from the data line DL may be supplied to the first node N1' sequentially via the second transistor M2', the first transistor M1', and the third transistor M3'. Thus, a voltage corresponding to the data signal DS and a threshold voltage of the first transistor M1' can be charged in the capacitor Cst.

The fourth transistor M4 may be electrically connected between the first node N1' and the initialization power source VINT. A gate electrode of the fourth transistor M4 may be electrically connected to the third scan line SL3 of the corresponding horizontal line. The fourth transistor M4 may be turned on in case that the third scan signal SC3 having the gate-on voltage is supplied to the third scan line SL3, to transfer the voltage of the initialization power source VINT to the first node N1'.

In an embodiment, the voltage of the initialization power source VINT may be equal to or lower than an optimum voltage of the data signal DS. Before the first scan signal SC1 having the gate-on voltage is supplied to each pixel PXL, the third scan signal SC3 having the gate-on voltage may be supplied to the third scan line SL3. Accordingly, before a data signal DS of each frame is supplied to each pixel PXL, the first node N1' may be initialized to the voltage of the initialization power source VINT. Accordingly, the first transistor M1' may be diode-connected in a forward direction during a period in which the first scan signal SC1 having the gate-on voltage is supplied to the first scan line SL1, regardless of the voltage of a data signal DS of a previous frame. Accordingly, a data signal DS of a corresponding frame may be transferred to the first node N1'.

The fifth transistor M5 may be electrically connected between the first power source VDD and the first transistor M1'. A gate electrode of the fifth transistor M5 may be electrically connected to the emission control line ECL of the corresponding horizontal line. The fifth transistor M5 may be turned off in case that the emission control signal ES having the gate-off voltage (for example, a logic low voltage or a low level voltage) is supplied to the emission control line ECL, and be turned on in other cases.

The sixth transistor M6 may be electrically connected between the first transistor M1' and the second node N2. A gate electrode of the sixth transistor M6 may be electrically connected to the emission control line ECL of the corresponding horizontal line. The sixth transistor M6 may be turned off in case that the emission control signal ES having the gate off voltage is supplied to the emission control line ECL, and be turned on in other cases.

The fifth and sixth transistors M5 and M6 may control an emission period. For example, in case that the fifth and sixth transistors M5 and M6 are turned on, a current path may be formed, through which a driving current can flow from the first power source VDD to the second power source VSS sequentially via the fifth transistor M5, the first transistor M1', the sixth transistor M6, and the light emitting unit EMU. In case that the fifth transistor M5 and/or the sixth transistor M6 are/is turned off, the light emission of the pixel PXL may be prevented while the current path is interrupted.

The seventh transistor M7 may be electrically connected between the second node N2 and an initialization power line INL. A gate electrode of the seventh transistor M7 may be electrically connected to the fourth scan line SL4 of the corresponding horizontal line.

The seventh transistor M7 may be electrically connected to the first electrode ET1 of the corresponding pixel PXL (for example, the first electrode ET1 of the light emitting unit EMU) through the second node N2, and be electrically connected to a first pad PD1 through the initialization power line INL. For example, the seventh transistor M7 may be electrically connected between the first electrode ET1 and the first pad PD1.

The seventh transistor M7 may be an initialization transistor for transferring the voltage of the initialization power source VINT to the first electrode ET1 of each pixel PXL during a driving period of the display device. For example, the seventh transistor M7 may be electrically connected between the first pad PD1 and the first electrode ET1 of the corresponding pixel PXL, to be turned on by the fourth scan signal SC4 having the gate-on voltage, which is supplied to the fourth scan line SL4 of the corresponding pixel row. In case that the seventh transistor M7 is turned on, the voltage of the initialization power source VINT, which is applied to the first pad PD1, may be transferred to each first electrode ET1 during the driving period of the display device.

In an embodiment, seventh transistors M7 of pixels PXL may share the fourth scan line SL4 disposed on the corresponding horizontal line, and be simultaneously turned on by the fourth scan signal SC4 having the gate-on voltage, which is supplied to the fourth scan line SL4. Seventh transistors M7 of pixels PXL sequentially arranged on different pixel rows may be connected to different gate lines (for example, fourth scan lines SL4 corresponding to respective pixel rows), to be sequentially turned on.

The scan signal SC and/or the initialization power source VINT, used to control an operation of the seventh transistor M7, may be variously changed. For example, in an embodiment, the gate electrode of the seventh transistor M7 may be connected to the first scan line SL1 or the third scan line SL3 of the corresponding horizontal line. The seventh transistor M7 may be turned on by the first scan signal SC1 or the third scan signal SC3, which has the gate-on voltage, to supply the voltage of the initialization power source VINT to the first electrode ET1 of the light emitting unit EMU. In an embodiment, the fourth transistor M4 and the seventh transistor M7 may be connected to different initialization power sources having different potentials. For example, in an embodiment, the pixel PXL may be connected to two different initialization power sources, and the first node N1' and the first electrode ET1 of the light emitting unit EMU may be initialized by initialization power sources having different potentials.

The capacitor Cst may be electrically connected between the first power source VDD and the first node N1'. The capacitor Cst may charge a voltage corresponding to the data signal DS supplied to the first node N1' and a threshold voltage of the first transistor M1' during each frame period.

Although a case where the transistors M included in the pixel circuit PXC are all p-type transistors is illustrated in FIG. 3, the disclosure is not necessarily limited thereto. For example, at least one of the first transistor M1', the second transistor M2', the third transistor M3', the fourth transistor M4, the fifth transistor M5, the sixth transistor M6 and the seventh transistor M7 may be changed to an n-type transistor. A gate-on voltage (for example, a logic high voltage) for turning on the n-type transistor may be a high level voltage.

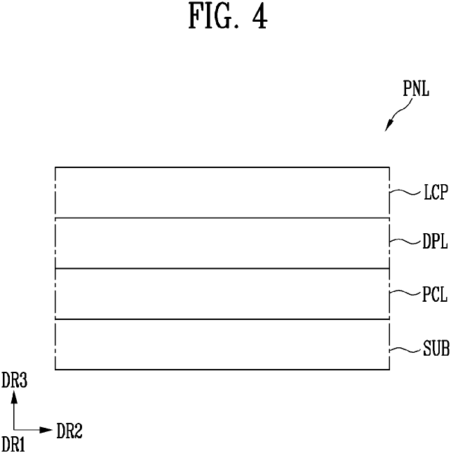

FIG. 4 is a schematic cross-sectional view illustrating a display panel in accordance with an embodiment.

Referring to FIGS. 1 to 4, the display panel PNL may include a substrate SUB, a pixel circuit layer PCL, a display element layer DPL, and a light control part LCP. In an embodiment, the substrate SUB, the pixel circuit layer PCL, the display element layer DPL, and the light control part LCP may be sequentially disposed along a display direction of the display panel PNL (for example, a third direction DR3).

The substrate SUB may constitute a base surface of the display panel PNL. Individual components of the display panel PNL may be disposed on the substrate SUB. For example, pixels PXL may be respectively disposed in pixel areas on the substrate SUB.

The pixel circuit layer PCL may be disposed on the substrate SUB. The pixel circuit layer PCL may include circuit elements constituting pixel circuits PXC of the pixels PXL and lines connected to the circuit elements. For example, transistors M and a capacitor Cst, which constitute a pixel circuit PXC of a corresponding pixel PXL, may be disposed in each pixel area of the pixel circuit layer PCL. Signal lines and/or power lines, which are connected to the pixels PXL, may be disposed in the pixel areas and/or at the periphery thereof. In an embodiment, in case that the pixels PXL do not include the pixel circuits PXC, the pixel circuit layer PCL may include only lines and/or only pads, which are used to supply a driving signal and/or a driving power source to the display element layer DPL, or be integral with the display element layer DPL.

The display element layer DPL may be disposed on the pixel circuit layer PCL. The display element layer DPL may include light emitting elements LD constituting light emitting units EMU of the pixels PXL, and electrodes and/or lines, which are connected to the light emitting elements LD. For example, at least one light emitting element LD constituting a light emitting unit EMU of each pixel PXL may be provided in each pixel area, for example, an emission area of the display element layer DPL. A first electrode ET1, a second electrode ET2, and/or a line, which are connected to the at least one light emitting element LD, may be provided in the emission area and/or at the periphery thereof.

In an embodiment, the light emitting element LD provided in the light emitting unit EMU of each pixel PXL may be connected to a pixel circuit PXC of the corresponding pixel PXL and at least one power line. The light emitting element LD may emit light with a luminance corresponding to an electrical signal (for example, a driving current) provided from the pixel circuit PXC. Light generated in the light emitting elements LD of the display element layer DPL may be emitted to the outside while passing through the light control part LCP.

The light control part LCP may be disposed on the display element layer DPL. In an embodiment, the light control part LCP may include color filters which allow light having a specific or given color and/or a wavelength band corresponding thereto to be selectively transmitted therethrough. For example, the light control part LCP may include a color filter of a first color (hereinafter, referred to as a “first color filter”) disposed at an upper portion of a first pixel PXL1 (or in the first pixel PXL1), a color filter of a second color (hereinafter, referred to as a “second color filter”) disposed at an upper portion of a second pixel PXL2 (or in the second pixel PXL2), and a color filter of a third color (hereinafter, referred to as a “third color filter”) disposed at an upper portion of a third pixel PXL3 (or in the third pixel PXL3).

In an embodiment, the light control part LCP may further include an additional component in addition to the color filters. For example, the light control part LCP may selectively further include a wavelength conversion pattern including color conversion particles (for example, wavelength conversion particles) and/or a light transmission pattern including light scattering particles.

FIG. 5 is a schematic cross-sectional view illustrating a display panel in accordance with an embodiment. For example, FIG. 5 schematically illustrates a section a display panel PNL with respect to one portion or a portion of the display area DA in which the pixel unit PXU shown in FIG. 1 is disposed.

In FIG. 5, any one transistor M (for example, a first transistor M1 including a lower conductive layer BML) connected to each light emitting element LD will be illustrated as an example of circuit elements which may be provided in each pixel area PXA of a pixel circuit layer PCL. The display panel PNL may further include the pixel circuit layer PCL, the circuit elements, and/or lines electrically connected to light emitting elements LD of a display element layer DPL.

For example, in FIG. 5, a pixel area PXA in which each pixel PXL is disposed will be described based on an emission area EMA of the pixel PXL. However, each pixel area PXA may include a pixel circuit area in which circuit elements constituting each pixel circuit PXC are disposed and an emission area EMA in which at least one light emitting element LD constituting each light emitting unit EMU is disposed. For example, a first pixel area PXA1 in which a first pixel PXL1 is disposed may include at least a first emission area EMA1, and selectively further include a portion of a non-emission area NEA, which is located at the periphery of the first light emission area EMA1. Similarly, a second pixel area PXA2 in which a second pixel PXL2 is disposed may include at least a second emission area EMA2, and selectively further include a portion of the non-emission area NEA, which is located at the periphery of the second emission area EMA2. A third pixel area PXA3 in which a third pixel PXL3 is disposed may include at least a third emission area EMA3, and selectively further include a portion of the non-emission area NEA, which is located at the periphery of the third emission area EMA3. In an embodiment, an emission area EMA of each pixel PXL may overlap a pixel circuit area of the corresponding pixel PXL, but the disclosure is not limited thereto.

Referring to FIGS. 1 and 5, the display panel PNL may include a substrate SUB, and the pixel circuit layer PCL, the display element layer DPL, and a light control part LCP, which are sequentially disposed on the substrate SUB.

The pixel circuit layer PCL may be provided on one surface or a surface of the substrate SUB. The pixel circuit layer PCL may include circuit elements constituting each pixel PXL. For example, transistors M and a capacitor Cst, which constitute a pixel circuit PXC of a corresponding pixel PXL, may be formed in each pixel area PXA of the pixel circuit layer PCL.

Also, the pixel circuit layer PCL may include various signal lines, power lines, and/or pads, which are connected to the pixels PXL. The pixel circuit layer PCL may include conductive layers constituting the various signal lines, the power lines, and/or the pads. The pixel circuit layer PCL may further include insulating layers respectively disposed between the conductive layers.

For example, a lower conductive layer BML may be disposed on the substrate SUB. The lower conductive layer BML may be formed as a single layer or a multi-layer, which is made of at least one of molybdenum (Mo), copper (Cu), aluminum (Al), chromium (Cr), gold (Au), titanium (Ti), nickel (Ni), neodymium (Nd), and indium tin oxide (ITO), or any alloy thereof.

A buffer layer BFL may be disposed on the lower conductive layer BML. The buffer layer BFL may prevent an impurity from being diffused into each circuit element. The buffer layer BFL may be a single layer, but may be a multi-layer including at least two layers. In case that the buffer layer BFL is provided as the multi-layer, the layers may be formed of a same material or a similar material or may be formed of different materials.

A semiconductor pattern SCP may be disposed on the buffer layer BFL. In an example, the semiconductor pattern SCP may include a first region in contact with a first transistor electrode TE1, a second region in contact with a second transistor electrode TE2, and a channel region located between the first and second regions. In an embodiment, one of the first and second regions may be a source region, and the other of the first and second regions may be a drain region.

In an embodiment, the semiconductor pattern SCP may be made of poly-silicon, amorphous silicon, oxide semiconductor, etc., within the spirit and the scope of the disclosure. The channel region of the semiconductor pattern SCP is a semiconductor pattern undoped with an impurity, and may be an intrinsic semiconductor. Each of the first and second regions of the semiconductor pattern SCP may be a semiconductor pattern doped with an impurity.

A gate insulating layer GI may be disposed on the buffer layer BFL and the semiconductor pattern SCP. In an example, the gate insulating layer GI may be disposed between the semiconductor pattern SCP and a first gate electrode GE1. The gate insulating layer GI may be a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A first gate conductive layer GAT1 may be disposed on the gate insulating layer GI. The first gate conductive layer GAT1 may include the first gate electrode GE1 of the transistor M. The first gate electrode GE1 may be disposed on the gate insulating layer GI to overlap the semiconductor pattern SCP in the third direction DR3.

The first gate conductive layer GAT1 may be formed as a single layer or a multi-layer, which is made of at least one of titanium (Ti), copper (Cu), indium tin oxide (ITO), molybdenum (Mo), chromium (Cr), gold (Au), nickel (Ni), and neodymium (Nd), or any alloy thereof. For example, the first gate conductive layer GAT1 may be formed as a multi-layer in which titanium (Ti), copper (Cu), and/or indium tin oxide (ITO) may be sequentially or repeatedly stacked each other.

A first interlayer insulating layer ILD1 may be disposed over the first gate conductive layer GAT1. In an example, the first interlayer insulating layer ILD1 may be disposed between the first gate electrode GE1 and the first and second transistor electrodes TE1 and TE2.

The first interlayer insulating layer ILD1 may be a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A second gate conductive layer GAT2 may be disposed on the first interlayer insulating layer ILD1. The second gate conductive layer GAT2 may include a second gate electrode GE2 of the transistor M. The second gate electrode GE2 may be disposed to overlap the first gate electrode GE1 in the third direction DR3 with the first interlayer insulating layer ILD1 interposed therebetween.

The second gate conductive layer GAT2 may be formed as a single layer or a multi-layer, which is made of at least one of titanium (Ti), copper (Cu), indium tin oxide (ITO), molybdenum (Mo), chromium (Cr), gold (Au), nickel (Ni), and neodymium (Nd), or any alloy thereof. For example, the second gate conductive layer GAT2 may be formed as a multi-layer in which titanium (Ti), copper (Cu), and/or indium tin oxide (ITO) may be sequentially or repeatedly stacked each other.

A second interlayer insulating layer ILD2 may be disposed over the second gate conductive layer GAT2. In an example, the second interlayer insulating layer ILD2 may be disposed between the second gate electrode GE2 and the first and second transistor electrodes TE1 and TE2.

The second interlayer insulating layer ILD2 may be a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A first source drain conductive layer SD1 may be disposed on the second interlayer insulating layer ILD2. The first source drain conductive layer SD1 may include the first and second transistor electrodes TE1 and TE2 of the transistor M. The first and second transistor electrodes TE1 and TE2 may be disposed to overlap the semiconductor pattern SCP in the third direction DR3. The first and second transistor electrodes TE1 and TE2 may be electrically connected to the semiconductor pattern SCP. For example, the first transistor electrode TE1 may be electrically connected to the first region of the semiconductor pattern SCP through a contact hole penetrating the second interlayer insulating layer ILD2, the first interlayer insulating layer ILD1, and/or the gate insulating layer GI. The second transistor electrode TE2 may be electrically connected to the second region of the semiconductor pattern SCP through a contact hole penetrating the second interlayer insulating layer ILD2, the first interlayer insulating layer ILD1, and/or the gate insulating layer GI. In an embodiment, any one of the first and second transistor electrodes TE1 and TE2 may be a source electrode, and the other of the first and second transistor electrodes TE1 and TE2 may be a drain electrode.

The first source drain conductive layer SD1 may be formed as a single layer or a multi-layer, which is made of at least one of aluminum (Al), molybdenum (Mo), chromium (Cr), gold (Au), titanium (Ti), nickel (Ni), neodymium (Nd), and indium tin oxide (ITO), or any alloy thereof.

A first via layer VIA1 may be disposed over the first source drain conductive layer SD1. The first via layer VIA1 may be a single layer or a multi-layer. In an example, the first via layer VIA1 may include an organic material such as acrylic resin, epoxy resin, phenolic resin, polyamides resin, polyimides resin, unsaturated polyesters resin, poly-phenylene ethers resin, poly-phenylene sulfides resin, or benzocyclobutene (BCB). However, the disclosure is not necessarily limited thereto, and the first via layer VIA1 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A second source drain conductive layer SD2 may be disposed on the first via layer VIA1. The second source drain conductive layer SD2 may include a bridge pattern BRP. The bridge pattern BRP may function to electrically connect the transistor M and a first electrode ET1 provided in a light emitting unit EMU of a corresponding pixel PXL to each other. For example, the bridge pattern BRP may be electrically connected to the first transistor electrode TE1 of the transistor M through a contact hole penetrating the first via layer VIA1. The first electrode ET1 of the corresponding pixel PXL may be electrically connected to the bridge pattern BRP through a contact hole CNT penetrating a second via layer VIA2 which will be described later.

The second source drain conductive layer SD2 may be formed as a single layer or a multi-layer, which is made of at least one of aluminum (Al), molybdenum (Mo), chromium (Cr), gold (Au), titanium (Ti), nickel (Ni), neodymium (Nd), and indium tin oxide (ITO), or any alloy thereof.

The second via layer VIA2 may be disposed over the second source drain conductive layer SD2. The second via layer VIA2 may be made of an organic material to planarize a lower step difference. For example, the second via layer VIA2 may include an organic material such as acrylic resin, epoxy resin, phenolic resin, polyamides resin, polyimides resin, unsaturated polyesters resin, poly-phenylene ethers resin, poly-phenylene sulfides resin, or benzocyclobutene (BCB). However, the disclosure is not necessarily limited thereto, and the second via layer VIA2 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The display element layer DPL may be disposed on the second via layer VIA2.

The display element layer DPL may include light emitting units EMU including first electrodes ET1, light emitting elements LD, and second electrodes ET2. Also, the display element layer DPL may further include a bank BNK and/or an insulating layer INS, disposed at the periphery of the light emitting elements LD, and a first passivation layer PSS1 covering or overlapping the light emitting units EMU.

For example, at least one light emitting element LD constituting a light emitting unit EMU of a corresponding pixel PXL, and a first electrode ET1 and a second electrode ET2, which are electrically connected to the light emitting element LD, may be disposed in each pixel area PXA of the display element layer DPL. In an example, the display element layer DPL may include a first electrode ET1 disposed in an emission area (hereinafter, referred to as the “first emission area EMA1”) of the first pixel PXL1 and at least one light emitting element LD disposed on the first electrode ET1, a first electrode ET1 disposed in an emission area (hereinafter, referred to as the “second emission area EMA2”) of the second pixel PXL2 and at least one light emitting element LD disposed on the first electrode ET1, a first electrode ET1 disposed in an emission area (hereinafter, referred to as the “third emission area EMA3”) of the third pixel PXL3 and at least one light emitting element LD disposed on the first electrode ET1, and second electrodes ET2 disposed on the light emitting elements LD.

A first electrode ET1 of each pixel PXL may be disposed on the pixel circuit layer PCL to be located in each emission area EMA. For example, the first electrode ET1 of the first pixel PXL1 may be disposed on the pixel circuit layer PCL to be located in the first emission area EMA1, the first electrode ET1 of the second pixel PXL2 may be disposed on the pixel circuit layer PCL to be located in the second emission area EMA2, and the first electrode ET1 of the third pixel PXL3 may be disposed on the pixel circuit layer PCL to be located in the third emission area EMA3. In an embodiment, each first electrode ET1 may be an anode electrode provided in a corresponding pixel (or a light emitting unit EMU of the corresponding pixel PXL). The first electrodes ET1 of the pixels PXL may be separated from each other.

Each first electrode ET1 may be electrically connected to at least one circuit element constituting a pixel circuit PXC of a corresponding pixel PXL. For example, the first electrode ET1 of the first pixel PXL1 may be electrically connected to at least one circuit element (for example, the transistor M of the first pixel PXL1) constituting the pixel circuit PXC of the first pixel PXL1. Similarly, the first electrode ET1 of the second pixel PXL2 may be electrically connected to at least one circuit element (for example, the transistor M of the second pixel PXL2) constituting the pixel circuit PXC of the second pixel PXL2, and the first electrode ET1 of the third pixel PXL3 may be electrically connected to at least one circuit element (for example, the transistor M of the third pixel PXL3) constituting the pixel circuit PXC of the third pixel PXL3.

The first electrodes ET1 may be disposed on the second via layer VIA2. The first electrodes ET1 may be electrically connected to bridge patterns BRP through contact holes CNT, respectively.

Each first electrode ET1 may be disposed on the bottom of a light emitting element LD provided in a corresponding pixel PXL, and be electrically connected to the light emitting element LD. For example, each first electrode ET1 may be in contact with a first end portion EP1 of a light emitting element LD provided in a corresponding pixel PXL, to be electrically connected to the first end portion EP1 of the light emitting element LD. In an embodiment, the first end portion EP1 may be a portion of the light emitting element LD including a first semiconductor layer SCL1 of the light emitting element LD and/or at least one electrode layer provided at the periphery thereof.

Each first electrode ET1 may transfer an electrical signal provided through a pixel circuit PXC of a corresponding pixel PXL to the first end portion EP1 of the light emitting element LD. For example, the first electrode ET1 may transfer the voltage of the first power source VDD supplied through each pixel circuit PXC to the first semiconductor layer SCL1 of the light emitting element LD provided in the corresponding pixel PXL.

In an embodiment, each first electrode ET1 may be a multi-layered electrode including a first sub-electrode ET1-1 and a second sub-electrode ET1-2, which are sequentially disposed on the second via layer VIA2. For example, the first sub-electrode ET1-1 may be disposed on the second via layer VIA2, and the second sub-electrode ET1-2 may be disposed between the first sub-electrode ET1-1 and the light emitting element LD. In an embodiment, the second sub-electrode ET1-2 may include a bonding metal bonding-coupled to each light emitting element LD.

Each of the first sub-electrode ET1-1 and the second sub-electrode ET1-2 may include at least one conductive material, to have conductivity, and the material constituting each of the first sub-electrode ET1-1 and the second sub-electrode ET1-2 is not particularly limited. In an example, each of the first sub-electrode ET1-1 and the second sub-electrode ET1-2 may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper Cu, or other conductive materials.

In an embodiment, at least one of the first sub-electrode ET1-1 and the second sub-electrode ET1-2 may include a reflective conductive material. For example, at least one of the first sub-electrode ET1-1 and the second sub-electrode ET1-2 may be formed as a metal layer including at least one of metals having high reflexibility in a visible light wavelength band, for example, reflective metals including aluminum (Al), gold (Au), and silver (Ag). Accordingly, the light efficiency of the pixels PXL can be improved.

Light emitting elements LD of corresponding pixels PXL may be disposed on the first electrodes ET1. In an embodiment, the light emitting elements LD may be directly disposed on the first electrodes ET1, to be electrically connected to the first electrodes ET1, respectively.

Each light emitting element LD may include a light emitting stack structure including a first semiconductor layer SCL1, an emitting layer EML (also, referred to as an “active layer”), and a second semiconductor layer SCL2, which are sequentially disposed on each first electrode ET1. For example, the light emitting element LD may include a first semiconductor layer SCL1, an emitting layer EML, and a second semiconductor layer SCL2, which are sequentially stacked toward a second end portion EP2 adjacent to each second electrode ET2 from the first end portion EP1 adjacent to each first electrode ET1.

In an embodiment, the first end portion EP1 may include a first surface (or lower surface) of the light emitting element LD and/or a peripheral area thereof. For example, the first end portion EP1 may include the first semiconductor layer SCL1 and/or a peripheral area thereof. In an embodiment, the first end portion EP1 may be in contact with any one first electrode ET1 corresponding to the corresponding light emitting element LD, to be electrically connected to the first electrode ET1.

In an embodiment, the second end portion EP2 may include a second surface (or upper surface) of the light emitting element LD and/or a peripheral area thereof. For example, the second end portion EP2 may include an area in which the second semiconductor layer SCL2 is disposed. In an embodiment, the second end portion EP2 may be in contact with any one second electrode ET2 corresponding to the corresponding light emitting element LD, to be electrically connected to the second electrode ET2.

In an embodiment, each light emitting element LD may be manufactured in a pillar shape through an etching process, or the like, and may be bonded onto each first electrode ET1. In descriptions of embodiments, the term “pillar shape” may include a rod-like shape or bar-like shape, such as a cylinder or a polyprism, and the shape of its section is not particularly limited.

In an embodiment, the light emitting element LD may have a size small to a degree of nanometer scale to micrometer scale. However, the size of the light emitting element LD is not limited thereto.

The first semiconductor layer SCL1 may include a first conductivity type semiconductor layer including a first conductivity type dopant. For example, the first semiconductor layer SCL1 may be a p-type semiconductor layer including a p-type dopant. In an embodiment, the first semiconductor layer SCL1 may be located at the first end portion EP1 of the light emitting element LD.

In an embodiment, the first semiconductor layer SCL1 may include a nitride-based semiconductor material or a phosphide-based semiconductor material. In an example, the first semiconductor layer SCL1 may include a nitride-based semiconductor material including at least one material among GaN, AlGaN, InGaN, AlInGaN, AlN, and InN, or a phosphide-based semiconductor material including at least one material among GaP, GaInP, AlGaP, AlGaInP, AlP, and InP. In an embodiment, the first semiconductor layer SCL1 may include a p-type dopant such as Mg. The material constituting the first semiconductor layer SCL1 is not limited thereto. The first semiconductor layer SCL1 may be formed by using various materials.

The emitting layer EML may be interposed between the first semiconductor layer SCL1 and the second semiconductor layer SCL2. The emitting layer EML may include a single- or multi-quantum well (QW) structure. In an embodiment, in case that the emitting layer EML is formed in the multi-quantum well structure, the emitting layer EML may have a structure in which a barrier layer, a strain reinforcing layer, and a well layer are periodically and/or repeatedly stacked each other as one unit. However, the emitting layer EML is not limited to the above-described embodiment.

In case that a voltage which is a threshold voltage or higher is applied to both ends of the light emitting element LD, light may be emitted as electron-hole pairs are combined in the emitting layer EML. For example, in case that an electrical signal is applied to the emitting layer EML through the first semiconductor layer SCL1 and the second semiconductor layer SCL2, light having a specific or given color and/or a wavelength band corresponding thereto as electron-hole pairs are combined in the emitting layer EML.

In an embodiment, the emitting layer EML may emit light having a visible light wavelength band, for example, light having a wavelength of about 400 nm to about 900 nm. For example, the emitting layer EML may emit light of blue, which has a wavelength in a range of about 450 nm to about 480 nm, light of green, which has a wavelength in a range of about 480 nm to about 500 nm, or light of red, which has a wavelength in a range of about 620 nm to about 750 nm. The color and/or wavelength band of light generated in the emitting layer EML may be changed.

In an embodiment, the emitting layer EML may include a nitride-based semiconductor material or a phosphide-based semiconductor material. In an example, the emitting layer EML may include a nitride-based semiconductor material including at least one material among GaN, AlGaN, InGaN, InGaAlN, AlN, InN, and AlInN, or a phosphide-based semiconductor material including at least one material among GaP, GaInP, AlGaP, AlGaInP, AlP, and InP. The material constituting the emitting layer EML is not limited thereto. The emitting layer EML may be formed by using various materials.

The second semiconductor layer SCL2 may include a second conductivity type semiconductor layer including a second conductivity type dopant. For example, the second semiconductor layer SCL2 may be an n-type semiconductor layer including an n-type dopant. In an embodiment, the second semiconductor layer SCL2 may be located at the second end portion EP2 of the light emitting element LD.

In an embodiment, the second semiconductor layer SCL2 may include a nitride-based semiconductor material or a phosphide-based semiconductor material. In an example, the second semiconductor layer SCL2 may include a nitride-based semiconductor material including at least one material among GaN, AlGaN, InGaN, AlInGaN, AlN, and InN, or a phosphide-based semiconductor material including at least one material among GaP, GaInP, AlGaP, AlGaInP, AlP, and InP. In an embodiment, the second semiconductor layer SCL2 may include an n-type dopant such as Si, Ge or Sn. The material constituting the second semiconductor layer SCL2 is not limited thereto. The second semiconductor layer SCL2 may be formed by using various materials.

In an embodiment, the first semiconductor layer SCL1 and the second semiconductor layer SCL2 include a same semiconductor material, and may include dopants of different conductivity types. In an embodiment, the first semiconductor layer SCL1 and the second semiconductor layer SCL2 include different semiconductor materials, and may include dopants of different conductivity types.

In an embodiment, the first semiconductor layer SCL1 and the second semiconductor layer SCL2 may have different thicknesses (or lengths) along the third direction DR3. In an example, in the third direction DR3, the second semiconductor layer SCL2 may have a thickness greater than that of the first semiconductor layer SCL1. Accordingly, the emitting layer EML may be located closer to the first end portion EP1 (for example, a p-type end portion) than the second end portion EP2 (for example, an n-type end portion).

The second semiconductor layer SCL2 may be located on the bottom of a second electrode ET2 of each pixel PXL, and be electrically connected to the second electrode ET2. In case that the pixels PXL shares one second electrode ET2, second semiconductor layers SCL2 provided in light emitting elements LD of the pixels PXL may be commonly connected to the one second electrode ET2.

Each light emitting element LD may further include an insulative film INF surrounding an outer circumferential surface (for example, a side surface) of the light emitting stack structure. For example, each light emitting element LD may further include an insulative film INF provided on a surface of the light emitting element LD to surround side surfaces of the first semiconductor layer SCL1, the emitting layer EML, and the second semiconductor layer SCL2. As the insulative film INF is provided in each light emitting element LD, a surface defect of the light emitting elements LD can be reduced or prevented, and a short defect through the light emitting elements LD can be prevented.

The insulative film INF may expose at least a portion of the light emitting stack structure at the first end portion EP1 and the second end portion EP2. Accordingly, the light emitting element LD can be electrically connected to each of the first electrode ET1 and the second electrode ET2.

The insulative film INF may include a transparent insulating material. Accordingly, light generated in each emitting layer EML can be emitted to the outside of the light emitting element LD while passing through the insulative film INF. For example, the insulative film INF may be a double layer, and layers constituting the double layer may include different material. In an example, the insulative film INF may be a double layer made of aluminum oxide (AlOₓ) and silicon oxide (SiOₓ), but the disclosure is not necessarily limited thereto. In an embodiment, the insulative film INF may be omitted.

The bank BNK may be disposed in the non-emission area NEA to be located between the emission areas EMA of the pixels PXL. For example, the bank BNK may be disposed at a boundary between adjacent pixels PXL and/or in an area between adjacent pixels PXL. In an embodiment, the bank BNK may be formed as a mesh type pattern having openings corresponding to the respective emission areas EMA of the pixels PXL in a plan view.

In an embodiment, the bank BNK may be formed to have a height equal to or smaller than that of the light emitting element LD. The height of the bank BNK may be set by considering a light emission characteristic of the light emitting elements LD (for example, an emission angle of light) and/or efficiency of a subsequent process. In an embodiment, the height of the bank BNK may be variously changed.

The bank BNK may include at least one light blocking material and/or at least one reflective material. For example, the bank BNK may include at least one black matrix material and/or a color filter material of a specific or given color. The bank BNK may include various materials.

The insulating layer INS may be disposed over the bank BNK. The insulating layer INS may cover or overlap at least a portion of the first electrode ET1. Also, the insulating layer INS may be provided between the light emitting elements LD disposed on the respective first electrodes ET1 (for example, bonded onto the respective first electrodes ET1). Accordingly, the outer circumferential surface (for example, the side surface) of the light emitting element LD may be covered or overlapped by the insulating layer INS. In an embodiment, the insulating layer INS may include a low refractive filler filled between the light emitting elements LD.

The insulating layer INS may include at least one insulating material, and the material or structure of the insulating layer INS is not particularly limited. For example, the insulating layer INS may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The second electrodes ET2 may be disposed on the insulating layer INS. For example, the pixels PXL may share one second electrode ET2. The second electrode ET2 may be electrically connected to second semiconductor layers SCL2 of the light emitting elements LD. For example, the second electrode ET2 may be disposed on or directly disposed on the light emitting elements LD. In an example, the second electrode ET2 may be formed on or directly formed on the second semiconductor layer SCL2 of the light emitting elements LD, to be electrically connected to the second semiconductor layers SCL2. For example, the second electrode ET2 may be electrically connected to the second semiconductor layers SCL2 of the light emitting elements LD via at least one electrode layer, etc., within the spirit and the scope of the disclosure.

The second electrode ET2 may include at least one conductive material, to have conductivity. In an embodiment, the second electrode ET2 may include a transparent conductive material. For example, the second electrode ET2 may include at least one material among conductive oxides such as Indium Tin Oxide (ITO), Indium Zinc Oxide (IZO), Indium Tin Zinc Oxide (ITZO), Zinc Oxide (ZnO), Aluminum doped Zinc Oxide (AZO), Gallium doped Zinc Oxide (GZO), Zinc Tin Oxide (ZTO), Gallium Tin Oxide (GTO), and Fluorine doped Tin Oxide (FTO), and conductive polymers such as poly(3,4-ethylenedioxythiophene) (PEDOT), or other transparent conductive material. The second electrode ET2 may be substantially transparent. Accordingly, the light emission efficiency (for example, a front light emission rate) of light generated in each light emitting element LD can be improved. Also, the second electrode ET2 may be a single layer or a multi-layer, and the shape, structure, and/or size of the second electrode ET2 are not particularly limited.

The first passivation layer PSS1 may be disposed over the second electrodes ET2. In an embodiment, the first passivation layer PSS1 may include at least one insulating material, and be a single layer or a multi-layer. For example, the first passivation layer PSS1 may include an organic insulating material, and substantially planarize a surface of the display element layer DPL.

The light control part LCP may be disposed on the display element layer DPL. The light control part LCP may be disposed on a path through which light generated from the light emitting elements LD is emitted.

In an embodiment, the light control part LCP may include a color filter layer CFL. Also, the light control part LCP may further include a color conversion layer CCL. For example, light emitting elements LD emitting light of a third color (for example, blue) may be disposed in the first pixel PXL1, the second pixel PXL2, and the third pixel PXL3, and a first wavelength conversion pattern WCP1 and a second wavelength conversion pattern WCP2, which include first color conversion particles and second color conversion particles, may be provided at upper portion of the first pixel PXL1 and the second pixel PXL2, respectively. Accordingly, a full-color image can be displayed in the display area DA. However, the disclosure is not necessarily limited thereto. For example, in an embodiment, the first pixel PXL1, the second pixel PXL2, and the third pixel PXL3 may include light emitting elements LD emitting lights of different colors. In an example, the first pixel PXL1, the second pixel PXL2, and the third pixel PXL3 may include light emitting elements LD emitting lights of red, green, and blue, respectively.

The color conversion layer CCL may be disposed on the first passivation layer PSS1. In an embodiment, at least one protective layer and/or at least one adhesive layer may be provided between the color conversion layer CCL the first passivation layer PSS1.

The color conversion layer CCL may include a wavelength conversion pattern WCP, a light transmission pattern LTP, and a light blocking pattern LBP.

The first wavelength conversion pattern WCP1 may be disposed to overlap the emission area EMA (for example, the first emission area EMA1) of the first pixel PXL1. For example, the first wavelength conversion pattern WCP1 may be disposed in a space defined by the light blocking pattern LBP, to overlap the first emission area EMA1 when viewed in a plan view.

The second wavelength conversion pattern WCP2 may be disposed to overlap the emission area EMA (for example, the second emission area EMA2) of the second pixel PXL2. For example, the second wavelength conversion pattern WCP2 may be disposed in a space defined by the light blocking pattern LBP, to overlap the second emission area EMA2 when viewed in a plan view.

The light transmission pattern LTP may be disposed to overlap the emission area EMA (for example, the third emission area EMA3) of the third pixel PXL3. For example, the light transmission pattern LTP may be disposed in a space defined by the light blocking pattern LBP, to overlap the third emission area EMA3.

In an embodiment, the light blocking pattern LBP may include openings respectively corresponding to the emission areas EMA (for example, the first, second, and third emission areas EMA1, EMA2, and EMA3). Each first wavelength conversion pattern WCP1 may be disposed in an opening of the light blocking pattern LBP in an area corresponding to each first emission area EMA1. Each second wavelength conversion pattern WCP2 may be disposed in an opening of the light blocking pattern LBP in an area corresponding to each second emission area EMA2. Each light transmission pattern LTP may be disposed in an opening of the light blocking pattern LBP in an area corresponding to each third emission area EMA3.

The first wavelength conversion pattern WCP1 may include first color conversion particles for converting light of the third color, which is emitted from the light emitting element LD provided in the first emission area EMA1, into light of a first color. For example, in case that the light emitting element LD provided in the first emission area EMA1 is a blue light emitting element emitting light of blue, and the first pixel PXL1 is a red pixel, the first wavelength conversion pattern WCP1 may include a first quantum dot (for example, a red quantum dot) for converting light of blue, which is emitted from the blue light emitting element, into light of red. The kind of the first color conversion particles and the color and/or wavelength of the light converted in the first wavelength conversion pattern WCP1 may be variously changed in an embodiment.

The second wavelength conversion pattern WCP2 may include second color conversion particles for converting light of the third color, which is emitted from the light emitting element LD provided in the second emission area EMA2, into light of a second color. For example, in case that the light emitting element LD provided in the second emission area EMA2 is a blue light emitting element emitting light of blue, and the second pixel PXL2 is a green pixel, the second wavelength conversion pattern WCP2 may include a second quantum dot (for example, a green quantum dot) for converting light of blue, which is emitted from the blue light emitting element, into light of green. The kind of the second color conversion particles and the color and/or wavelength of the light converted in the second wavelength conversion pattern WCP2 may be variously changed in an embodiment.

The light transmission pattern LTP may be provided to efficiently emit the light of the third color, which is emitted from the light emitting element LD provided in the third emission area EMA3. In an example, in case that the light emitting element LD provided in the third emission area EMA3 is a blue light emitting element emitting light of blue, and the third pixel PXL3 is a blue pixel, the light transmission pattern LTP may include at least one kind of light scattering particles (for example, silica or other light scattering particles) for improving the light efficiency of the pixel PXL by scattering the light of blue, which is emitted from the blue light emitting element.

The light scattering particles are not to be disposed only in the third emission area EMA3. For example, the light scattering particles may be selectively included in the first wavelength conversion pattern WCP1 and/or the second first wavelength conversion pattern WCP2.

The light blocking pattern LBP may be disposed on the non-emission area NEA of the display element layer DPL. In an embodiment, the light blocking pattern LBP may be formed as a mesh type pattern including openings corresponding to emission areas EMA while surrounding each of the emission areas EMA when viewed in a plan view. Also, the light blocking pattern LBP may surround wavelength conversion patterns WCP and light transmission patterns LTP, which are provided in the respective emission areas EMA.

The light blocking pattern LBP may include at least one light blocking material that blocks the transmission of light and absorbs light. For example, the light blocking pattern LBP may include an organic material including at least one of graphite, carbon black, a black pigment, and a black dye, and at least one material among metals including chromium (Cr), or various other light blocking materials. The bank BNK and the light blocking pattern LBP may include a same light blocking material or include different light blocking materials.

A second passivation layer PSS2 may be disposed over the wavelength conversion patterns WCP and the light transmission patterns LTP. In an embodiment, the second passivation layer PSS2 may include at least one insulating material, and be a single layer or a multi-layer. For example, the second passivation layer PSS2 may include an organic insulating material, and substantially planarize a surface of the color conversion layer CCL.

The color filter layer CFL may be disposed on the color conversion layer CCL. The color filter layer CFL may include color filters CF provided in the respective emission areas EMA. For example, the color filter layer CFL may include a first color filter CF1 disposed in the first emission area EMA1 of the first pixel PXL1, a second color filter CF2 disposed in the second emission area EMA2 of the second pixel PXL2, and a third color filter CF3 disposed in the third emission area EMA3 of the third pixel PXL3. Also, the color filter layer CFL may include a planarization layer PLA covering or overlapping the color filters CF.

Each first color filter CF1 may be located above the light emitting element LD of each first pixel PXL1, and allow light of the first color to be selectively transmitted therethrough. For example, the first color filter CF1 may include a color filter material of the first color, which allows light of the first color to be transmitted therethrough and blocks transmission of lights of the second color and the third color.

Each second color filter CF2 may be located above the light emitting element LD of each second pixel PXL2, and allow light of the second color to be selectively transmitted therethrough. For example, the second color filter CF2 may include a color filter material of the second color, which allows light of the second color to be transmitted therethrough and blocks transmission of lights of the first color and the third color.

Each third color filter CF3 may be located above the light emitting element LD of each third pixel PXL3, and allow light of the third color to be selectively transmitted therethrough. For example, the third color filter CF3 may include a color filter material of the third color, which allows light of the third color to be transmitted therethrough and blocks transmission of lights of the first color and the second color.

The planarization layer PLA may be disposed over the color filters CF. In an embodiment, the planarization layer PLA may include an organic insulating material, and substantially planarize a surface of the color filter layer CFL.

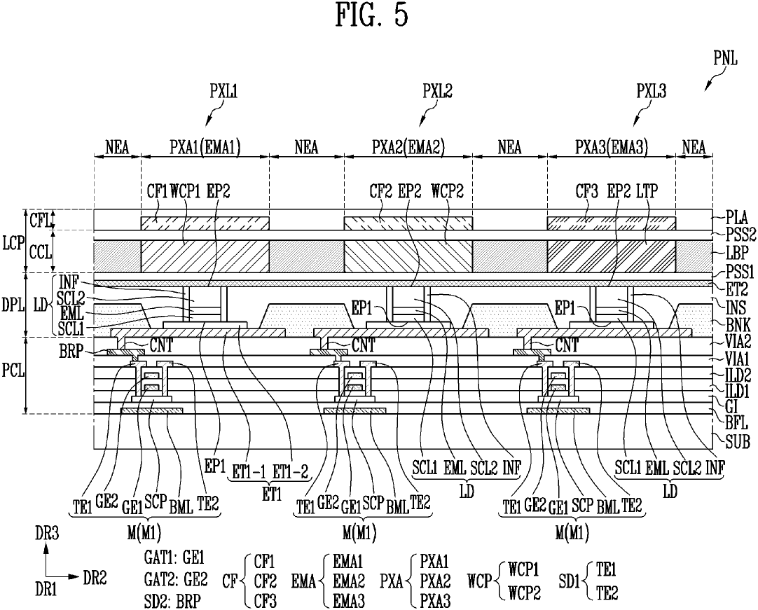

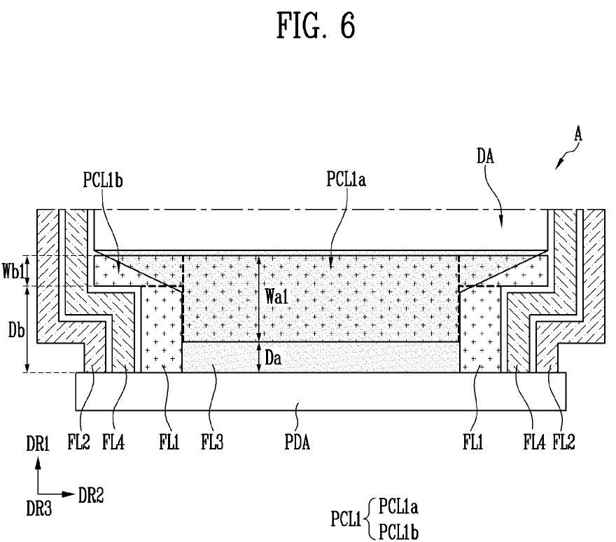

FIG. 6 is an enlarged schematic plan view of area A shown in FIG. 1. For example, FIG. 6 schematically illustrates a planar arrangement of lines in the non-display area NDA adjacent to the display area DA.

Referring to FIGS. 1 to 6, fan-out lines FL1, FL2, FL3, and FL4 may be disposed in the non-display area NDA. At least one of the fan-out lines FL1, FL2, FL3, and FL4 may be a line which provides a signal to each pixel PXL and is connected to signal lines, for example, a scan line, a data line, an emission control line, and the like, which are connected to each pixel PXL, or a line connected to signal lines, for example, a control line, a sensing line, and the like, which are connected to each pixel PXL so as to compensate for an electrical characteristic change of each pixel PXL in real time.

As described above, a first fan-out line FL1 may be electrically connected to a first power connection line PCL1. The first power connection line PCL1 may include an outer part PCL1b disposed at a relatively outer portion in the non-display area NDA and a central part PCL1a disposed at a relatively central portion. The central part PCL1a of the first power connection line PCL1 may be disposed between outer parts PCL1b. For example, the central part PCL1a of the first power connection line PCL1 may be disposed between the above-described first fan-out lines FL1.

In an embodiment, a distance Da between the central part PCL1a of the first power connection line PCL1 and the pad area PDA may be different from that Db between the outer part PCL1b of the first power connection line PCL1 and the pad area PDA. For example, the distance Da between the central part PCL1a of the first power connection line PCL1 and the pad area PDA may be shorter than that Db between the outer part PCL1b of the first power connection line PCL1 and the pad area PDA.

In an embodiment, a width Wa1 of the central part PCL1a of the first power connection line PCL1 in the first direction DR1 may be different from that Wb1 of the outer part PCL1b of the first power connection line PCL1 in the first direction DR1. For example, the width Wa1 of the central part PCL1a of the first power connection line PCL1 in the first direction DR1 may be wider than that Wb1 of the outer part PCL1b of the first power connection line PCL1 in the first direction DR1. As described above, in case that the width Wa1 of the central part PCL1a of the first power connection line PCL1 in the first direction DR1 is formed to become relatively wide, a line heating problem can be minimized through current distribution of the central part PCL1a of the first power connection line PCL1, and thus the light emission uniformity of the display panel PNL can be improved.

A second fan-out line FL2 may include a bent part which extends along the first direction DR1 in the non-display area NDA and is partially bent. However, the disclosure is not limited thereto, and the arrangement and shape of the second fan-out line FL2 may be various changed. The second fan-out line FL2 may be disposed in a same layer as the above-described first fan-out line FL1. In an example, the second fan-out line FL2 may be simultaneously formed with the first fan-out line FL1 through a same process, but the disclosure is not necessarily limited thereto. The second fan-out line FL2 has been described in detail with reference to FIG. 1, and therefore, overlapping portions will be omitted.

A third fan-out line FL3 may be disposed between first fan-out lines FL1 in the non-display area NDA. The third fan-out line FL3 may be disposed in a layer different from that of the first fan-out line FL1 and/or the second fan-out line FL2. In an example, the third fan-out line FL3 may be disposed on the bottom of the first fan-out line FL1 and/or the second fan-out line FL2, but the disclosure is not necessarily limited thereto. In an embodiment, the third fan-out line FL3 may at least partially overlap the first fan-out line FL1.

A fourth fan-out line FL4 may include a bent part which extends along the first direction DR1 in the non-display area NDA and is partially bent. The fourth fan-out line FL4 may be disposed between the first fan-out line FL1 and the second fan-out line FL2. Each of the above-described first to fourth fan-out lines FL1, FL2, FL3, and FL4 may be one line or multiple lines. In case that each of the first to fourth fan-out lines FL1, FL2, FL3, and FL4 includes multiple lines, the lines may be of different conductive layers or may be of a same conductive layer.

FIGS. 7 to 11 are schematic cross-sectional views illustrating a display panel in accordance with an embodiment. For example, FIGS. 7 to 11 schematically illustrate sections of the display panel PNL with respect to one portion or a portion of the non-display area NDA.

Referring to FIGS. 1 to 7, a first gate conductive layer GAT1 and/or a second gate conductive layer GAT2 may include the above-described third fan-out line FL3.

The second gate conductive layer GAT2 may be disposed on the above-described first interlayer insulating layer ILD1. The second gate conductive layer GAT2 may be formed as a single layer or a multi-layer, which is made of at least one of titanium (Ti), copper (Cu), indium tin oxide (ITO), molybdenum (Mo), chromium (Cr), gold (Au), nickel (Ni), and neodymium (Nd), or any alloy thereof. For example, the second gate conductive layer GAT2 may be formed as a multi-layer in which titanium (Ti), copper (Cu), and/or indium tin oxide (ITO) may be sequentially or repeatedly stacked each other.

A second interlayer insulating layer ILD2 may be disposed over the second gate conductive layer GAT2. In an example, the second interlayer insulating layer ILD2 may be disposed between the second gate conductive layer GAT2 and the above-described first source drain conductive layer SD1.

The second interlayer insulating layer ILD2 may be a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A first source drain conductive layer SD1 and/or a second source drain conductive layer SD2 may include the above-described first fan-out line FL1. The first fan-out line FL1 may be disposed in a same layer as the above-described first power line PL1 and/or the above-described first power connection line PCL1. In an example, the first fan-out line FL1, the first power line PL1, and/or the first power connection line PCL1 may be simultaneously formed through a same process, but the disclosure is not necessarily limited thereto.

In an embodiment, the second source drain conductive layer SD2 constituting the first fan-out line FL1, the first power line PL1, and/or the first power connection line PCL1 may be electrically connected to the first source drain conductive layer SD1 through contact holes penetrating a first via layer VIA1.

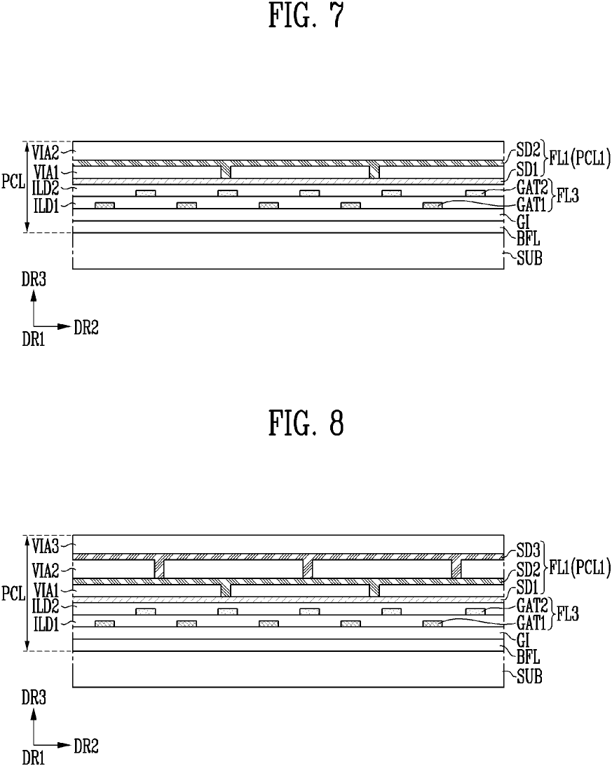

Referring to FIG. 8, this embodiment may be distinguished from an embodiment shown in FIG. 7, in that a first source drain conductive layer SD1, a second source drain conductive layer SD2, and/or a third source drain conductive layer SD3 may include a first fan-out line FL1.

The first fan-out line FL1 may be disposed in a same layer as a first power line PL1 and/or a first power connection line PCL1. In an example, the first fan-out line FL1, the first power line PL1, and/or the first power connection line PCL1 may be simultaneously formed through a same process, but the disclosure is not limited thereto.

The third source drain conductive layer SD3 may be disposed on the above-described second via layer VIA2. The third source drain conductive layer SD3 may be formed as a single layer or a multi-layer, which is made of at least one of aluminum (Al), molybdenum (Mo), chromium (Cr), gold (Au), titanium (Ti), nickel (Ni), neodymium (Nd), and indium tin oxide (ITO), or any alloy thereof.

A third via layer VIA3 may be disposed on the third source drain conductive layer SD3. The third via layer VIA3 may be made of an organic material to planarize a lower step difference. For example, the third via layer VIA3 may include an organic material such as acrylic resin, epoxy resin, phenolic resin, polyamides resin, polyimides resin, unsaturated polyesters resin, poly-phenylene ethers resin, poly-phenylene sulfides resin, or benzocyclobutene (BCB). However, the disclosure is not necessarily limited thereto, and the third via layer VIA3 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, the second source drain conductive layer SD2 constituting the first fan-out line FL1, the first power line PL1, and/or the first power connection line PCL1 may be electrically connected to the first source drain conductive layer SD1 through contact holes penetrating the first via layer VIA1. The third source drain conductive layer SD3 constituting the first fan-out line FL1, the first power line PL1, and/or the first power connection line PCL1 may be electrically connected to the second source drain conductive layer SD2 through contact holes penetrating the second via layer VIA2.

Referring to FIG. 9, this embodiment may be distinguished from an embodiment shown in FIG. 7, in that a lower conductive layer BML and/or a first gate conductive layer GAT1 include a third fan-out line FL3, and a first source drain conductive layer SD1 may include a first fan-out line FL1.

The lower conductive layer BML may be disposed between the substrate SUB and the buffer layer BFL. The lower conductive layer BML may be formed as a single layer or a multi-layer, which is made of at least one of molybdenum (Mo), copper (Cu), aluminum (Al), chromium (Cr), gold (Au), titanium (Ti), nickel (Ni), neodymium (Nd), and indium tin oxide (ITO), or any alloy thereof.

The first source drain conductive layer SD1 may include the first fan-out line FL1. The first fan-out line FL1 may be disposed in a same layer as the first power line PL1 and/or the first power connection line PCL1. In an example, the first fan-out line FL1, the first power line PL1, and/or the first power connection line PCL1 may be simultaneously formed through a same process, but the disclosure is not necessarily limited thereto.

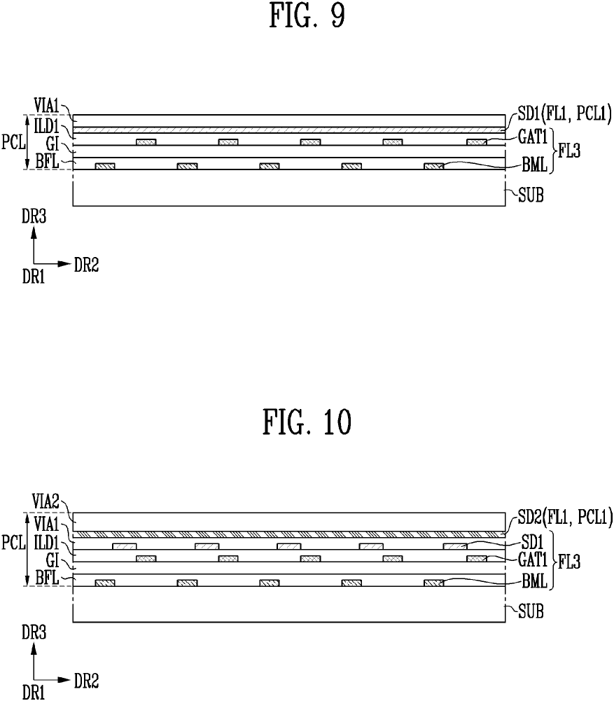

Referring to FIG. 10, this embodiment may be distinguished from an embodiment shown in FIG. 7, in that a lower conductive layer BML, a first gate conductive layer GAT1, and/or a first source drain conductive layer SD1 may include a third fan-out line FL3, and a second source drain conductive layer SD2 may include a first fan-out line FL1. The lower conductive layer BML, the first gate conductive layer GAT1, the first source drain conductive layer SD1, and/or the second source drain conductive layer SD2 have been described above, and therefore, overlapping portions will be omitted.

Referring to FIG. 11, this embodiment may be distinguished from an embodiment shown in FIG. 7, in that a lower conductive layer BML, a first gate conductive layer GAT1, a second gate conductive layer GAT2, and/or a first source drain conductive layer SD1 may include a third fan-out line FL3, and a second source drain conductive layer SD2 includes a first fan-out line FL1. The lower conductive layer BML, the first gate conductive layer GAT1, the second gate conductive layer GAT2, the first source drain conductive layer SD1, and/or the second source drain conductive layer SD2 have been described above, and therefore, overlapping descriptions will be omitted.

In accordance with the above-described embodiment, the width Wa1 of the central part PCL1a of the first power connection line PCL1 in the first direction DR1 is formed to become relatively wide, thereby minimizing a line heating problem through current distribution of the central part PCL1a of the first power connection line PCL1. Thus, the light emission uniformity of the display panel PNL can be improved.

Hereinafter, an embodiment will be described. In the following embodiment, components identical to those described above are designated by like reference numeral, and overlapping descriptions will be omitted or simplified.

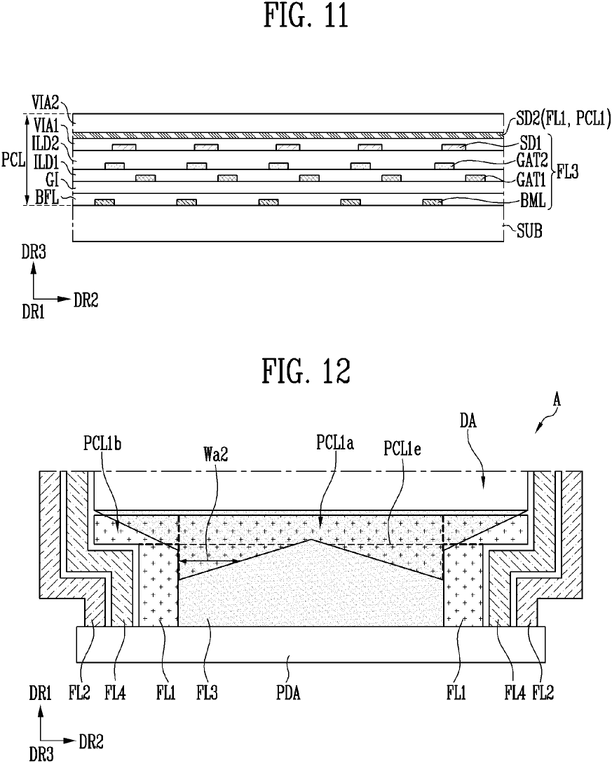

FIG. 12 is an enlarged schematic plan view of the area A in accordance with an embodiment.

Referring to FIG. 12, this embodiment may be distinguished from an embodiment shown in FIGS. 1 to 11, in that the width Wa2 of the central part PCL1a of the first power connection line PCL1 in the second direction DR2 may be changed according to a position.

For example, the width Wa2 of the central part PCL1a of the first power connection line PCL1 in the second direction DR2 may become wider as becoming more adjacent to the display area DA from the pad area PDA. As described above, in case that the width Wa2 of the central part PCL1a of the first power connection line PCL1 in the second direction DR2 is formed to become wider as becoming more adjacent to the display area DA, a line heating problem can be minimized through current distribution of the central part PCL1a of the first power connection line PCL1, and thus the light emission uniformity of the display panel PNL can be improved.

In an embodiment, an area in which the width Wa2 in the second direction DR2 becomes wide in the central part PCL1a of the first power connection line PCL1 may correspond to an extension part PCL1e. The extension part PCL1e may have a shape extending in the second direction DR2 and/or the opposite direction of the second direction DR2 from one side or a side of each of the first fan-out lines FL1. Also, the extension part PCL1e may have a shape extending in the opposite direction of the first direction DR1 from one side or a side of the first power connection line PCL1.

The extension part PCL1e may be disposed in a same layer as the first fan-out line FL1, the first power connection line PCL1, and/or the first power line PL1. For example, the extension part PCL1e may be of conductive layers constituting the first fan-out line FL1, the first power connection line PCL1, and/or the first power line PL1, which are described with reference to FIGS. 7 to 11. In an example, the extension part PCL1e, the first fan-out line FL1, the first power connection line PCL1, and/or the first power line PL1 may be simultaneously formed through a same process, but the disclosure is not necessarily limited thereto.

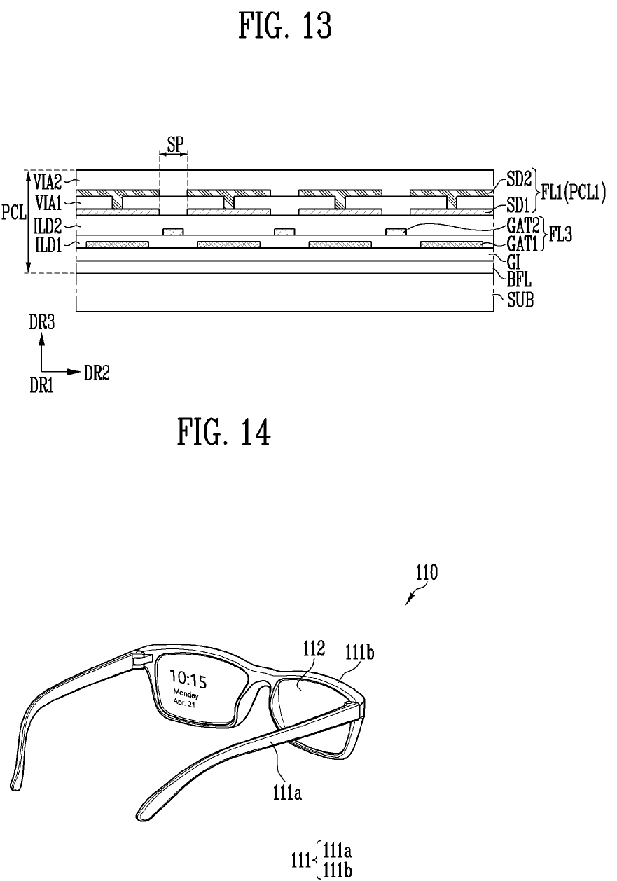

FIG. 13 is a schematic cross-sectional view illustrating a display panel in accordance with an embodiment. For example, FIG. 13 schematically illustrates a section of the display panel PNL with respect to one portion or a portion of the non-display area NDA.

Referring to FIG. 13, a first power connection line PCL1 may further include slit patterns SP at least partially overlapping the above-described third fan-out line FL3.

For example, a first gate conductive layer GAT1 and/or a second gate conductive layer GAT2 may include the third fan-out line FL3, and a first source drain conductive layer SD1 and the second source drain conductive layer SD2 may include a first fan-out line FL1, the first power connection line PCL1, and/or a first power line PL1. The first power connection line PCL1 may include slit patterns SP at least partially overlapping the third fan-out line FL3 so as to minimize an increase in capacitance due to overlapping of the first power connection line PCL1 with the third fan-out line FL3 disposed on the bottom thereof. For example, the first source drain conductive layer SD1 and/or the second source drain conductive layer SD2, constituting the first power connection line PCL1, may include slit patterns SP overlapping the second gate conductive layer GAT2 constituting the third fan-out line FL3. However, the disclosure is not necessarily limited thereto, and the first source drain conductive layer SD1 and/or the second source drain conductive layer SD2, constituting the first power connection line PCL1, may include slit patterns SP overlapping the first gate conductive layer GAT1 constituting the third fan-out line FL3. The first fan-out line FL1 including the first power connection line PCL1 may include slit patterns SP at least partially overlapping the third fan-out line FL3.

Hereinafter, electronic devices will be described, to which the display device in accordance with the above-described embodiments can be applied.

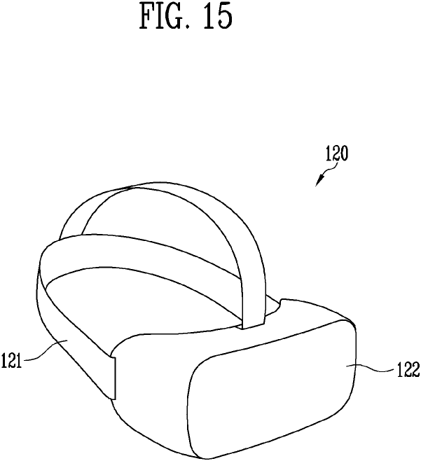

FIGS. 14 to 17 are views illustrating electronic devices in accordance with various embodiments.

Referring to FIG. 14, the display device in accordance with the above-described embodiments may be applied to smart glasses. The smart glasses may include a frame 111 and a lens part 112. The smart glasses 110 are a wearable electronic device which can be worn on the face of a user, and may have a structure in which a portion of the frame 111 is folded or unfolded. For example, the smart glasses 110 may be a wearable device for Augmented Reality (AR).

The frame 111 may include a housing 111b supporting the lens part 112 and a leg part 111a for allowing the user to wear the smart glasses 110. The leg part 111a may be connected to the housing 111b by a hinge to be folded or unfolded.

A battery, a touch pad, a microphone, and/or a camera may be built in the frame 111. A projector for outputting light and/or a processor for controlling a light signal may be built in the frame 111.

The lens part 112 may be an optical member which allows light to be transmitted therethrough or allows light to be reflected thereby. The lens part 112 may include glass and/or transparent synthetic resin.

The display device in accordance with the above-described embodiments may be applied to the lens part 112. In an example, a user may recognize an image displayed by a light signal transmitted from the projector of the frame 111 through the lens part 112. For example, the user may recognize information such as a time, a data, and the like, which are displayed on the lens part 112.

Referring to FIG. 15, the display device in accordance with the above-described embodiments may be applied to a Head Mounted Display (HMD). The HMD may include a head mounted band 121 and a display accommodating case 122. For example, the HMD 120 is a wearable electronic device which can be worn on the head of a user.

The head mounted band 121 may be connected to the display accommodating case 122, to fix the display accommodating case 122. As shown in FIG. 15, the head mounted band 121 may include a horizontal band and a vertical band to allow the HMD 120 to be fixed to the head of the user. The horizontal band may be provided to surround a side portion of the head of the user, and the vertical band may be provided to surround an upper portion of the head of the user. However, the disclosure is not limited thereto, and the head mounted band 121 may be formed in the shape of a glasses frame or a helmet.

The display accommodating case 122 accommodates the display device, and may include at least one lens. The at least one lens may provide an image to the user. For example, the display device in accordance with the above-described embodiments may be applied to a left-eye lens and a right-eye lens, which are implemented in the display accommodating case 122.

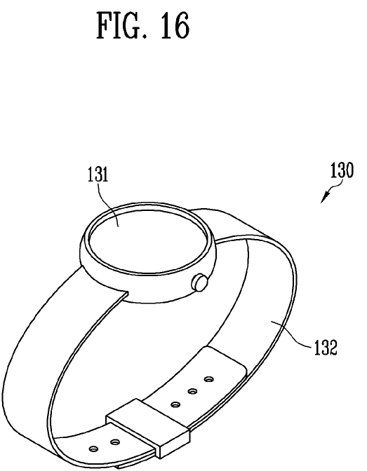

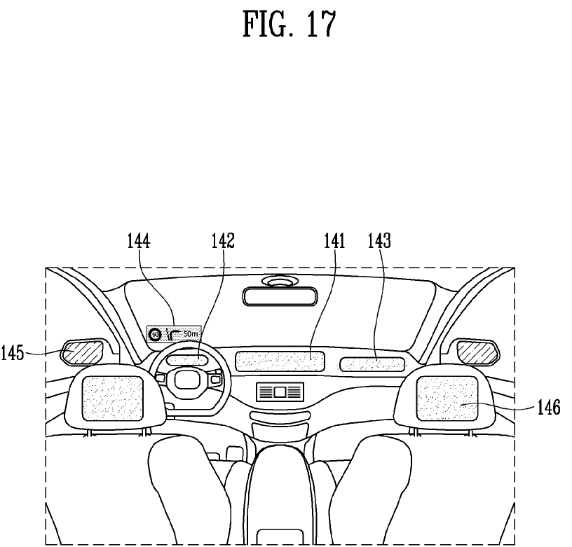

Referring to FIG. 16, the display device in accordance with the above-described embodiments may be applied to a smart watch. The smart watch may include a display part 131 and a strap part 132. The smart watch 130 is a wearable electronic device, and may be mounted on a wrist of a user. The display device in accordance with the above-described embodiments may be applied to the display part 131. For example, the display part 131 may provide image data including information of a time, a data, and the like within the spirit and the scope of the disclosure.

Referring to FIG. 17, the display device in accordance with the above-described embodiments may be applied to an automotive display. In an example, the automotive display may mean an electronic device provided at the inside and/or the outside of a vehicle to provide image data.

For example, the display device in accordance with the above-described embodiments may be applied to at least one of an infortainment panel 141, a cluster 142, a co-driver display 143, a head-up display 144, a side mirror display 145, and a rear seat display 146, which are provided in the vehicle.

In accordance with the disclosure, a width of a central part of a first power connection line is formed to become relatively wide, thereby minimizing a line heating problem through current distribution of the central part of the first power connection line. Thus, the light emission uniformity of the display panel can be improved.

Embodiments have been disclosed herein, and although terms are employed, they are used and are to be interpreted in a generic and descriptive sense only and not for purpose of limitation. In some instances, as would be apparent to one of ordinary skill in the art, features, characteristics, and/or elements described in connection with an embodiment may be used singly or in combination with features, characteristics, and/or elements described in connection with other embodiments unless otherwise indicated. Accordingly, it will be understood by those of skill in the art that various changes in form and details may be made without departing from the spirit and scope of the disclosure as set forth in the following claims.

What is claimed is:

1. A display device comprising:
a display area and a non-display area;
pixels disposed in the display area;
a pad area including pads, the pad area being disposed in the non-display area;
first power lines electrically connected to the pixels in the display area;
first fan-out lines extending in a first direction in the non-display area, the first fan-out lines being electrically connected to the pads; and
a first power connection line extending in a second direction intersecting the first direction in the non-display area, the first power connection line electrically connecting the first power lines to the first fan-out lines,
wherein a width of a central part of the first power connection line in the first direction is wider than a width of an outer part of the first power connection line in the first direction.

2. The display device of claim 1, wherein the central part of the first power connection line is disposed between the first fan-out lines.

3. The display device of claim 1, wherein a distance between the central part of the first power connection line and the pad area is shorter than a distance between the outer part of the first power connection line and the pad area.

4. The display device of claim 1, wherein a width of the central part of the first power connection line in the second direction expands in a direction adjacent to the display area from the pad area.

5. The display device of claim 1, further comprising:
second power lines electrically connected to the pixels in the display area; and
second fan-out lines electrically connected to the pads in the non-display area.

6. The display device of claim 5, wherein the pads include:
a first pad electrically connected to the first fan-out lines; and
a second pad electrically connected to the second fan-out lines.

7. The display device of claim 6, wherein
the first fan-out lines are supplied with a first power source from the first pad,
the second fan-out lines are supplied with a second power source from the second pad,
the first power source is a high-potential driving power source, and
the second power source is a low-potential driving power source.

8. The display device of claim 5, further comprising:
third fan-out lines disposed in the non-display area,
wherein the first fan-out lines are disposed on the third fan-out lines.

9. The display device of claim 8, wherein the first power connection line includes slit patterns at least partially overlapping the third fan-out lines in a plan view.

10. A display device comprising:
a display area and a non-display area;
pixels disposed in the display area;
pads disposed in the non-display area;
first power lines electrically connected to the pixels in the display area;
first fan-out lines extending in a first direction in the non-display area, the first fan-out lines being electrically connected to the pads;
a first power connection line extending in a second direction intersecting the first direction in the non-display area, the first power connection line electrically connecting the first power lines to the first fan-out lines; and
an extension part extending from at least one of a side of the first fan-out lines and a side of the first power connection line.

11. The display device of claim 10, wherein the first fan-out lines, the first power connection line, and the extension part are disposed on a same layer.

12. The display device of claim 10, further comprising:
a first conductive layer disposed on a substrate;
a second conductive layer disposed on the first conductive layer;
a third conductive layer disposed on the second conductive layer; and
a fourth conductive layer disposed on the third conductive layer,
wherein at least one of the third conductive layer and the fourth conductive layer includes the first fan-out lines, the first power connection line, and the extension part.

13. The display device of claim 12, wherein the fourth conductive layer is electrically connected to the third conductive layer through a contact hole penetrating a first via layer disposed between the third conductive layer and the fourth conductive layer.

14. The display device of claim 12, further comprising:
a fifth conductive layer disposed on the fourth conductive layer,
wherein the fifth conductive layer includes the first fan-out lines, the first power connection line, and the extension part.

15. The display device of claim 14, wherein the fifth conductive layer is electrically connected to the fourth conductive layer through a contact hole penetrating a second via layer disposed between the fourth conductive layer and the fifth conductive layer.

16. The display device of claim 12, further comprising:
second power lines electrically connected to the pixels in the display area; and
second fan-out lines electrically connected to the pads in the non-display area.

17. The display device of claim 16, wherein the second fan-out lines and the first fan-out lines are disposed on a same layer.

18. The display device of claim 16, further comprising:
third fan-out lines disposed in the non-display area,
wherein at least one of the first conductive layer and the second conductive layer includes the third fan-out lines.

19. The display device of claim 18, further comprising:
a lower conductive layer disposed between the substrate and the first conductive layer,
wherein the lower conductive layer includes the third fan-out lines.

20. The display device of claim 18, wherein at least one of the third conductive layer and the fourth conductive layer includes slit patterns at least partially overlapping the second conductive layer in a plan view.
